(19) United States
(12) Patent Application Publication
(10) Pub. No.: US 2026/0227699 A1
(43) Pub. Date: Aug. 6, 2026

(54) CHEMICAL-RESISTANT PROTECTIVE FILM

(71) Applicant: ISSAN CHEMICAL CORPORATION, Tokyo (JP)

(72) Inventors: Kazuhiko KINOSHITA, Toyama-shi (JP); Tokio NISHITA, Toyama-shi (JP); Gun SON, Toyama-shi (JP)

(73) Assignee: NISSAN CHEMICAL CORPORATION, Tokyo (JP)

(21) Appl. No.: 19/146,269

(22) PCT Filed: Mar. 8, 2024
(86) PCT No.: PCT/JP2024/009104

§ 371 Date: Jul. 8, 2025

(30) Foreign Application Priority Data
Mar. 13, 2023 (JP) 2023-038981

(51) Int. Cl. G03F 7/09; C08G 59/32; C08G 59/62; C08G 59/66; C08G 59/68; G03F 7/16; H10P 50/00; H10P 50/28; H10P 50/64; H10P 50/68; H10P 76/20

(52) U.S. Cl. CPC G03F 7/094; C08G 59/3218; C08G 59/621; C08G 59/66; C08G 59/686; G03F 7/168; H10P 50/287; H10P 50/642; H10P 50/683; H10P 50/69; H10P 50/73; H10P 76/2041

(57) ABSTRACT

A protective-film forming composition that can form a protective film having excellent resistance to a semiconductor wet etching solution, that enables dry etching at a high etching speed to achieve a high etch rate (ER), and that can also be effectively used as a resist underlayer-film forming composition. The protective-film forming composition against the semiconductor wet etching solution contains (A) a compound or polymer having an epoxy structure represented by the following Formula (I), (B) a compound having a thiol structure, and (C) a solvent,

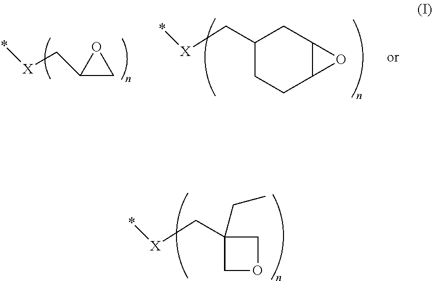

in Formula (I), * represents a binding site; n represents 1 or 2; and when n=1, X represents an ether bond, an ester bond, or an amide bond, and when n=2, X represents a nitrogen atom or an amide bond.

### TECHNICAL FIELD

The present invention relates to a protective-film forming composition excellent in resistance particularly to a semiconductor wet etching solution, preferably an acidic or basic hydrogen peroxide aqueous solution, in a lithography process in semiconductor manufacturing. The present invention also relates to a protective film containing the composition, a method for manufacturing a resist-patterned substrate to which the protective film is applied, and a method for manufacturing a semiconductor device.

### BACKGROUND ART

In semiconductor manufacturing, a lithography process of providing a resist underlayer film between a substrate and a resist film formed on the substrate and forming a resist pattern having a desired shape is widely known.

Patent Literature 1 discloses an antireflective coating composition containing a polymer having a glycidyl group and a polymer having an aromatic group substituted with a hydroxy group or the like and used together with an overcoated photoresist, and a method for forming a photoresist underlayer film using the composition and performing exposure, development, and pattern formation.

Patent Literature 2 discloses a method for forming a photoresist relief image by applying a composition containing a resin containing an epoxy reactive group such as a hydroxy group and a crosslinked resin containing an epoxy group to a base material to form a photoresist layer thereon.

### CITATION LIST

### Patent Literatures

Patent Literature 1: JP 2017-107185 A
Patent Literature 2: JP 2017-187764 A

### SUMMARY OF INVENTION

### Technical Problem

In a case where a protective film for a semiconductor substrate is formed by using a protective-film forming composition, and a base substrate is processed by wet etching, with the protective film used as an etching mask, it is demanded for the protective film to have a good masking function (that is, the masked part can protect the substrate) against a semiconductor wet etching solution.

In the related art, a reaction between an epoxy group and a hydroxy group has been used for crosslinking of a protective film in order to develop resistance to a wet etching chemical solution, and the hydroxy group is required to be directly connected to an aromatic ring structure due to its reactivity. In addition, since a composition having an aromatic ring structure usually has a high carbon content, the etching speed during dry etching is low, and it is difficult to achieve a high etch rate (ER).

Therefore, an object of the present invention is to provide a protective-film forming composition that can form a protective film having excellent resistance to a semiconductor wet etching solution, that enables dry etching at a high etching speed to achieve a high etch rate (ER), and that can also be effectively used as a resist underlayer-film forming composition.

### Solution to Problem

As a result of intensive studies to solve the above problems, the present inventors have found a composition that achieves an epoxy-based crosslinking system not relying solely on an aromatic ring structure by using thiol groups instead of hydroxy groups, has high resistance to a wet etching solution, and enables dry etching at a high etching speed, thereby forming a protective film capable of achieving a high etch rate (ER), and have completed the present invention.

That is, the present invention includes the following aspects.

[1] A protective-film forming composition against a semiconductor wet etching solution, the protective-film forming composition containing:
(A) a compound or polymer having an epoxy structure represented by the following Formula (I);
(B) a compound having a thiol structure; and
(C) a solvent,

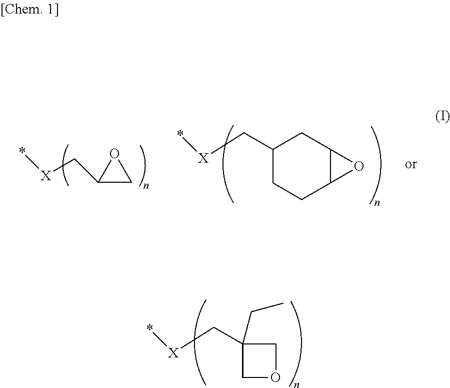

in Formula (I), * represents a binding site; n represents 1 or 2; and when n=1, X represents an ether bond, an ester bond, or an amide bond, and when n=2, X represents a nitrogen atom or an amide bond.

[2] The protective-film forming composition according to [1], further containing (D) a curing agent.

[3] The protective-film forming composition according to [1] or [2], further containing (E) a compound or polymer having a phenolic hydroxy group.

[4] The protective-film forming composition according to [1], in which the compound (A) is a compound having a partial structure represented by the following Formula (III),

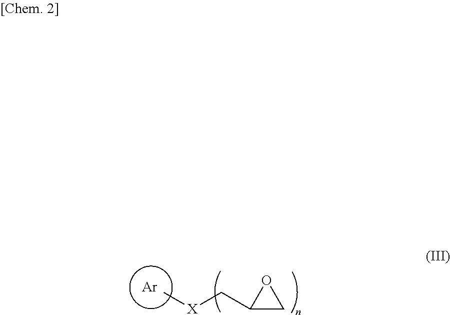

in Formula (III), Ar represents a benzene ring, a naphthalene ring, or an anthracene ring; and n represents 1 or 2; and when n=1, X represents an ether bond, an ester bond, or an amide bond, and when n=2, X represents a nitrogen atom or an amide bond.

[5] The protective-film forming composition according to [1], in which the polymer (A) is a polymer having a novolac structure having a unit structure represented by the following Formula (1-1),

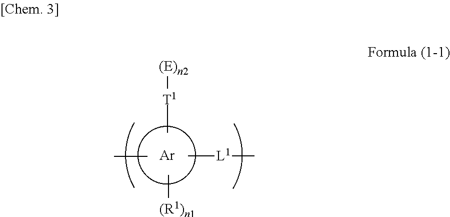

in Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer of 0 to 3, L¹ represents a single bond or an alkylene group having 1 to 10 carbon atoms, n2 represents 1 or 2, E represents a group having an epoxy group or a group having an oxetanyl group, T¹ represents an alkylene group having 1 to 10 carbon atoms, which may be interrupted by an ether bond, an ester bond, or an amide bond when n2=1, and T¹ represents a trivalent hydrocarbon group having 1 to 10 carbon atoms, which may be interrupted by a nitrogen atom or an amide bond when n2=2.

[6] The protective-film forming composition according to [1], in which the compound (B) having a thiol structure is a polyfunctional thiol compound represented by the following Formula (10-1),

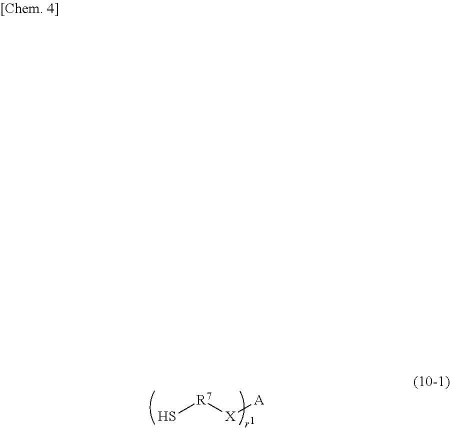

in Formula (10-1), R⁷ represents a single bond or a linear or branched alkylene group having 1 to 6 carbon atoms, X represents a single bond or an ester bond, A represents an organic group having 2 to 12 carbon atoms or a heteroatom, and r¹ represents an integer of 2 to 6.

[7] The protective-film forming composition according to [2], in which the curing agent (D) is a base.

[8] The protective-film forming composition according to [7], in which the base is an imidazole-based compound.

[9] The protective-film forming composition according to [8], in which the base is represented by the following Formula (B1),

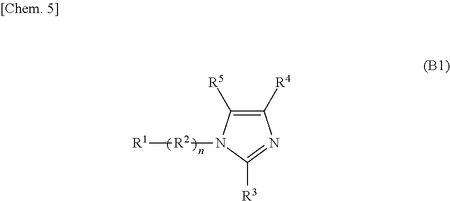

in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or less carbon atoms, which may be substituted, R⁵ represents a hydrogen atom, a formyl group, an alkyl group having 1 to 4 carbon atoms, which may be substituted, or an alkoxyalkyl group having 4 or less carbon atoms, which may be substituted, and n represents 0 or 1.

[10] The protective-film forming composition according to [3], in which the compound or polymer having a phenolic hydroxy group (E) has two or more phenolic hydroxy groups.

[11] The protective-film forming composition according to [3], in which the compound or polymer having a phenolic hydroxy group (E) is a polymer having a unit structure represented by the following Formula (3-1),

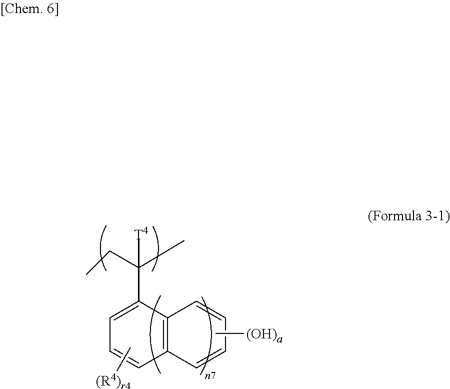

in the formula, T⁴ represents a hydrogen atom or an alkyl group having 1 to 10 carbon atoms, which may be substituted with a halogeno group; R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group; r4 represents an integer of 0 to 3; n7 represents an integer of 0 to 2; and a represents an integer of 1 to 6.

[12]A protective film against a semiconductor wet etching solution, in which the protective film is a baked product of a coating film containing the protective-film forming composition according to any one of [1] to [11].

[13]A resist underlayer-film forming composition including:
(A) a compound or polymer having an epoxy structure represented by the following Formula (I);
(B) a compound having a thiol structure; and
(C) a solvent,

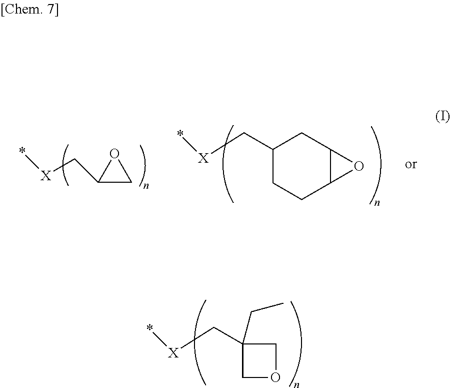

in Formula (I), * represents a binding site; n represents 1 or 2; and when n=1, X represents an ether bond, an ester bond, or an amide bond, and when n=2, X represents a nitrogen atom or an amide bond.

[14]A method for manufacturing a substrate with a protective film, the method including: a step of applying the protective-film forming composition according to any one of [1] to [11] to a semiconductor substrate, and baking the composition to form a protective film, in which the method is used for manufacturing a semiconductor.

[15]A method for manufacturing a resist-patterned substrate, the method including: a step of applying the protective-film forming composition according to any one of [1] to [11] or the resist underlayer-film forming composition according to [13] to a semiconductor substrate and baking the composition to form a protective film as a resist underlayer film; and a step of forming a resist film on the protective film and then exposing and developing the composition to form a resist pattern, in which the method is used for manufacturing a semiconductor.

[16]A method for manufacturing a semiconductor device, the method including a step of: forming a protective film using the protective-film forming composition according to any one of claims 1 to 11 on a semiconductor substrate having a surface on which an inorganic film is optionally formed; forming a resist pattern on the protective film; dry etching the protective film using the resist pattern as a mask to expose the inorganic film or the surface of the semiconductor substrate; and wet etching the inorganic film or the semiconductor substrate using the protective film after the dry etching as a mask by a semiconductor wet etching solution, followed by cleaning.

[17]A method for manufacturing a semiconductor device, the method including a step of: forming a resist underlayer film using the resist underlayer-film forming composition according to [13] on a semiconductor substrate having a surface on which an inorganic film is optionally formed; forming a resist pattern on the resist underlayer film; dry etching the resist underlayer film using the resist pattern as a mask to expose the inorganic film or the surface of the semiconductor substrate; and etching the inorganic film or the semiconductor substrate using the resist underlayer film as a mask after the dry etching.

### Advantageous Effects of Invention

According to the present invention, it is possible to provide the protective-film forming composition that can form a protective film having excellent resistance to a semiconductor wet etching solution, that enables dry etching at a high etching speed to achieve a high etch rate (ER), and that can also be effectively used as a resist underlayer-film forming composition.

### DESCRIPTION OF EMBODIMENTS

Hereinafter, the present invention will be described in detail. Note that the description of the constituent requirements described below is an example for describing the present invention, and the present invention is not limited to the content thereof.

### (Protective-Film Forming Composition Against Semiconductor Wet Etching Solution)

A protective-film forming composition against a semiconductor wet etching solution of the present invention contains
(A) a compound or polymer having an epoxy structure represented by the following Formula (I),
(B) a compound having a thiol structure, and
(C) a solvent.

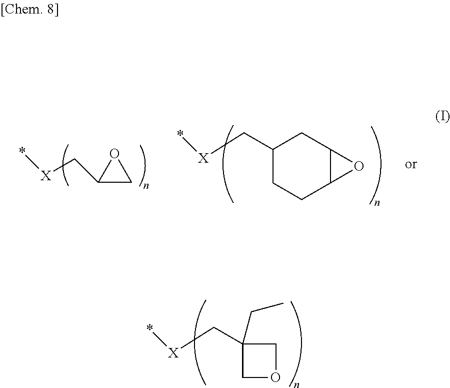

In Formula (I), * represents a binding site; n represents 1 or 2; and when n=1, X represents an ether bond, an ester bond, or an amide bond, and when n=2, X represents a nitrogen atom or an amide bond.

The protective-film forming composition of the present invention further contains (D) a curing agent.

In addition, the protective-film forming composition of the present invention may further contain (E) a compound or polymer having a phenolic hydroxy group.

Furthermore, the protective-film forming composition of the present invention may further contain (F) a compound having a hydroxy group and at least one of a hydroxy group or a carbonyl group.

The present inventors have found that a protective-film forming composition containing (A) a compound or polymer having an epoxy structure represented by the above Formula (I), (B) a compound having a thiol structure, and (D) a solvent, and more preferably further containing (D) a curing agent, (E) a compound or polymer having a phenolic hydroxy group, and (F) a compound having a hydroxy group and at least one of a hydroxy group or a carbonyl group can form a protective film that has a high resistance to a wet etching solution, and enables dry etching at a high etching speed to achieve a high etch rate (ER), and have completed the present invention.

A high etch rate (ER) is presumed to result from the effective retention of the thiol group-containing compound (B) in the cured film, due to crosslinking of the thiol group-containing compound (B) with the compound or polymer (A) having an epoxy structure, and the absence of an aromatic ring structure in the thiol group-containing compound (B). In addition, it can be expected that the etch rate can be controlled by adjusting the addition amount of the thiol group-containing compound (B).

### <(A) Compound or Polymer>

The compound or polymer (A) used in the present invention has an epoxy structure represented by the above Formula (I).

Examples of a more preferred embodiment of the compound or polymer (A) include a polymer represented by the following first aspect and a compound represented by the following second aspect.

### <<First Aspect>>

Examples of the polymer (A) used in the present invention include the following polymers.

Examples of such a polymer (hereinafter, it is also referred to as a polymer in the first aspect) include a polymer having a novolac structure having a unit structure represented by the following Formula (1-1) and an acrylic polymer having a unit structure represented by the following Formula (1-3).

As the polymer in the first aspect, for example, a polymer having a novolac structure is represented by the following formula (1-1).

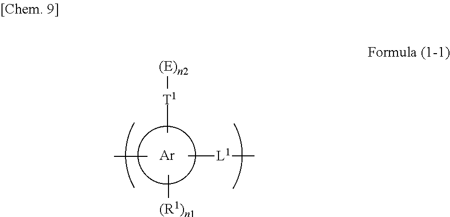

In Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer of 0 to 3, L¹ represents a single bond or an alkylene group having 1 to 10 carbon atoms, n2 represents 1 or 2, E represents a group having an epoxy group or a group having an oxetanyl group, T¹ represents an alkylene group having 1 to 10 carbon atoms, which may be interrupted by an ether bond, an ester bond, or an amide bond when n2=1, and T¹ represents a trivalent hydrocarbon group having 1 to 10 carbon atoms, which may be interrupted by a nitrogen atom or an amide bond when n2=2.

Examples of the alkyl group having 1 to 10 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, a methoxy group, an ethoxy group, a methoxymethyl group, an ethoxymethyl group, a methoxyethyl group, an ethoxyethyl group, a hydroxymethyl group, a 1-hydroxyethyl group, a 2-hydroxyethyl group, a methylamino group, a dimethylamino group, a diethylamino group, an aminomethyl group, a 1-aminoethyl group, a 2-aminoethyl group, a methylthio group, an ethylthio group, a mercaptomethyl group, a 1-mercaptoethyl group, and a 2-mercaptoethyl group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

An example of the alkyl group having 1 to 10 carbon atoms which is substituted with or interrupted by a heteroatom in R¹ is an alkoxy group having 1 to 10 carbon atoms.

Examples of the alkoxy group having 1 to 10 carbon atoms include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, an n-heptyloxy group, an n-octyloxy group, and an n-nonyloxy group.

The unit structure represented by Formula (1-1) may be one kind or a combination of two or more kinds. For example, a copolymer having a plurality of unit structures in which Ar is the same kind may be used, and for example, a copolymer having a plurality of unit structures in which Ar is different in kind, such as a copolymer having a unit structure in which Ar has a benzene ring and having a unit structure having a naphthalene ring, is not excluded from the technical scope of the present application.

The phrase “may be interrupted” means that in the case of an alkylene group having 2 to 10 carbon atoms, any carbon-carbon atom bond in the alkylene group is interrupted by a heteroatom (that is, an ether bond in the case of oxygen, and a sulfide bond in the case of sulfur), an ester bond, or an amide bond, and in the case of one carbon atom (that is, a methylene group), either one of the carbons of the methylene group has a heteroatom (that is, an ether bond in the case of oxygen, and a sulfide bond in the case of sulfur), an ester bond, or an amide bond.

T¹ represents a hydrocarbon group having 1 to 10 carbon atoms (including an alkylene group and a trivalent hydrocarbon group), which may be interrupted by an ether bond, an ester bond, a nitrogen atom, or an amide bond, and is preferably a combination of an ether bond and a methylene group (that is, when “-T¹-(E)n2” in Formula (1-1) is a glycidyl ether group), a combination of an ester bond and a methylene group, or a combination of an amide bond and a methylene group.

The alkyl group having 1 to 10 carbon atoms, which may be substituted with a heteroatom, means that one or more hydrogen atoms of the alkyl group having 1 to 10 carbon atoms are substituted with a heteroatom (preferably a halogeno group).

L¹ represents a single bond or an alkylene group having 1 to 10 carbon atoms, and is preferably represented by the following Formula (1-2),

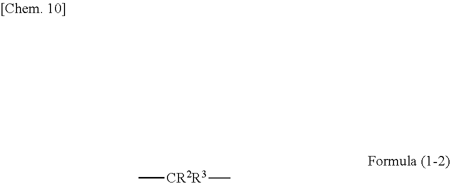

in Formula (1-2), R² and R³ each independently represent a hydrogen atom, a methyl group, an ethyl group, an n-propyl group, an i-propyl group, a cyclopropyl group, an n-butyl group, an i-butyl group, an s-butyl group, a t-butyl group, or a cyclobutyl group, and R² and R³ may be bonded to each other to form a ring having 3 to 6 carbon atoms); and among these, both R² and R³ are preferably hydrogen atoms (that is, —(CR²R³)— is a methylene group).

The halogeno group refers to halogen-X (F, Cl, Br, I) substituted with hydrogen.

E in Formula (1-1) is more preferably a group having an epoxy group.

The polymer having a novolac structure in the first aspect is not particularly limited as long as it satisfies, for example, the unit structure of Formula (1-1). The polymer may be produced by a known method. A commercially available product may also be used. Examples of the commercially available product include a heat-resistant epoxy novolac resin EOCN (registered trademark) series (manufactured by Nippon Kayaku Co., Ltd., and an epoxy novolac resin D.E.N (registered trademark) series (manufactured by Dow Chemical Japan, Ltd.).

A weight-average molecular weight of the polymer having a novolac structure in the first aspect is 100 or more, 500 to 200,000, 600 to 50,000, or 700 to 10,000.

Examples of the polymer having a novolac structure in the first aspect include those having the following unit structure.

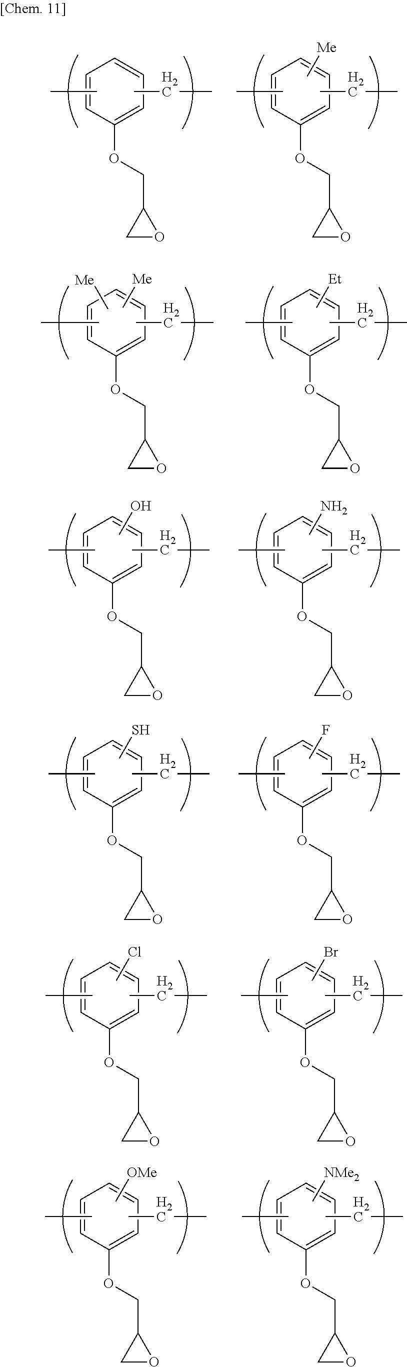

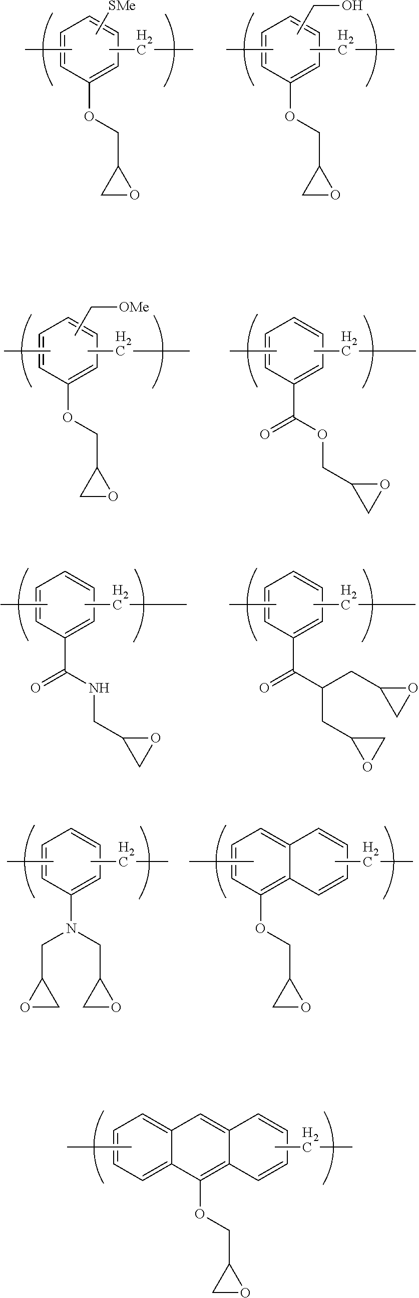

Me represents a methyl group, and Et represents an ethyl group.

As the polymer in the first aspect, for example, the acrylic polymer is represented by the following Formula (1-3),

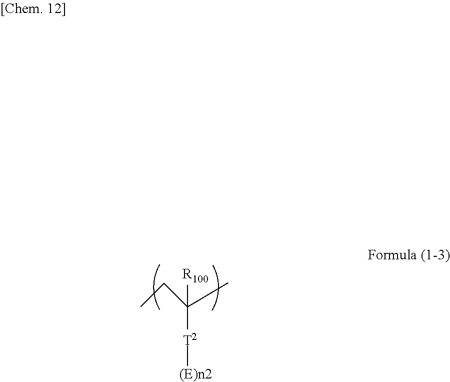

in Formula (1-3), R₁₀₀ represents a hydrogen atom or a methyl group, n2 represents 1 or 2, E represents a group having an epoxy group or a group having an oxetanyl group, T² represents an alkylene group having 1 to 10 carbon atoms, which may be interrupted by an ether bond, an ester bond, or an amide bond when n2=1, and T² represents a trivalent hydrocarbon group having 1 to 10 carbon atoms, which may be interrupted by a nitrogen atom or an amide bond when n2=2.

A weight-average molecular weight of the acrylic polymer in the first aspect is 100 to 20,000, 300 to 10,000, or 500 to 5,000.

### <<Second Aspect>>

Examples of the compound (A) used in the present invention include the following compounds.

Such a compound (hereinafter, also referred to as a compound in the second aspect) is a compound having no repeating structural unit,
the compound has a terminal group (A1), a polyvalent group (A2), and a linking group (A3),
the terminal group (A1) is bonded only to the linking group (A3),
the polyvalent group (A2) is bonded only to the linking group (A3),
the linking group (A3) is bonded on one hand to the terminal group (A1) and on the other hand to the polyvalent group (A2), and may optionally be bonded to another linking group (A3),
the terminal group (A1) has any of structures of the following Formula (I),

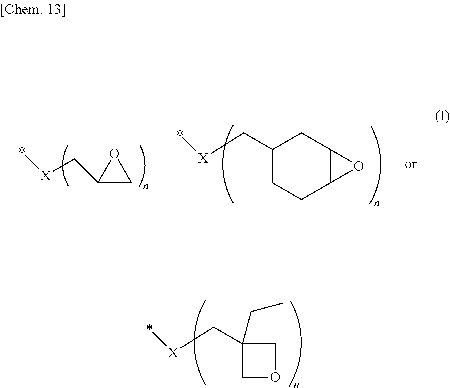

in Formula (I), * represents a binding site to the linking group (A3); n represents 1 or 2; and when n=1, X represents an ether bond, an ester bond, or an amide bond, and when n=2, X represents a nitrogen atom or an amide bond,
the polyvalent group (A2) is a divalent to tetravalent group selected from the group consisting of:
—O—;
an aliphatic hydrocarbon group;
a combination of an aromatic hydrocarbon group having less than 10 carbon atoms and an aliphatic hydrocarbon group; and
a combination of an aromatic hydrocarbon group having 10 or more carbon atoms and —O—, and
the linking group (A3) represents an aromatic hydrocarbon group.

The phrase “having no repeating structural unit” means to exclude a so-called polymer having a repeating structural unit, such as a polyolefin, a polyester, a polyamide, or a poly(meth)acrylate. The weight-average molecular weight of the compound (A) is preferably 300 or more and 1,500 or less.

The “bond” between the terminal group (A1), the polyvalent group (A2), and the linking group (A3) means a chemical bond, and this usually means a covalent bond but does not preclude an ionic bond.

The polyvalent group (A2) is a divalent to tetravalent group.

Therefore, the aliphatic hydrocarbon group in the definition of the polyvalent group (A2) is a divalent to tetravalent aliphatic hydrocarbon group.

Non-limiting examples of the divalent aliphatic hydrocarbon group include alkylene groups such as a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

When hydrogen at any site is removed from these groups, and the site is converted into a linking bond, trivalent and tetravalent groups are derived.

Examples of the aromatic hydrocarbon group having less than 10 carbon atoms in the definition of the polyvalent group (A2) include benzene, toluene, xylene, mesitylene, cumene, styrene, and indene.

Examples of the aliphatic hydrocarbon group that is combined with the aromatic hydrocarbon group having less than 10 carbon atoms include, in addition to the above-described alkylene groups, alkyl groups such as a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1 methyl-n-propyl group, a 1-ethyl-2 methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and a decyl group.

Any of the aromatic hydrocarbon group having less than 10 carbon atoms and the aliphatic hydrocarbon group in the definition of the polyvalent group (A2) may be bonded to the linking group (A3).

Examples of the aromatic hydrocarbon group having 10 or more carbon atoms in the definition of the polyvalent group (A2) include naphthalene, azulene, anthracene, phenanthrene, naphthacene, triphenylene, pyrene, and chrysene.

It is preferable that the aromatic hydrocarbon group having 10 or more carbon atoms in the definition of the polyvalent group (A2) is bonded to the linking group (A3) through —O—.

Examples of the aromatic hydrocarbon group in the definition of the linking group (A3) include the above-described aromatic hydrocarbon group having less than 10 carbon atoms and the above-described aromatic hydrocarbon group having 10 or more carbon atoms.

Preferably, the compound (A) has two or more linking groups (A3).

The compound in the second aspect is preferably represented by, for example, the following formula (II).

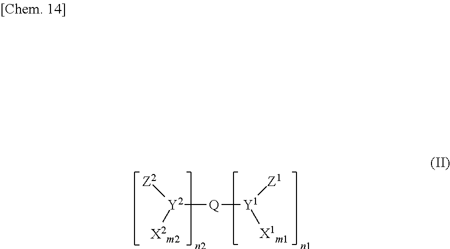

In Formula (II),
Z¹ and Z² each independently represent

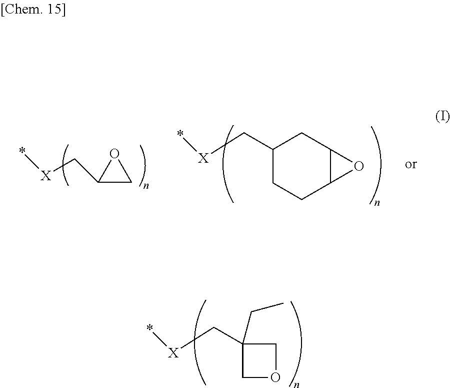

in Formula (I), * represents Y¹ or a binding site to Y²; n represents 1 or 2; and when n=1, X represents an ether bond, an ester bond, or an amide bond, and when n=2, X represents a nitrogen atom or an amide bond,
Y¹ and Y² each independently represent an aromatic hydrocarbon group,
X¹ and X² each independently represent —Y¹—Z¹ or —Y²—Z²,
n1 and n2 each independently represent an integer of 0 to 4, where any one of n1 and n2 is 1 or more,
m1 defined in (X¹)m1 represents 0 or 1,
m2 defined in (X²)m2 represents 0 or 1, and
Q represents a (n1+n2)-valent group selected from the group consisting of —O—, an aliphatic hydrocarbon group, a combination of an aromatic hydrocarbon group having less than 10 carbon atoms and an aliphatic hydrocarbon group, and a combination of an aromatic hydrocarbon group having 10 or more carbon atoms and —O—.

It is preferable that Q is a divalent to tetravalent group.

In Formula (II), Z and Z² correspond to the terminal group (A1), Q corresponds to the polyvalent group (A2), Y¹ and Y² correspond to the linking group (A3), and the description, examples, and the like thereof are as described above.

The compound in the second aspect preferably has a partial structure represented by, for example, the following Formula (III),

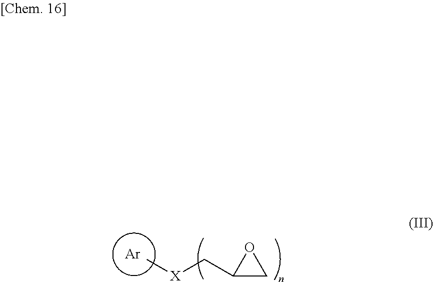

in Formula (III), Ar represents a benzene ring, a naphthalene ring, or an anthracene ring; and n represents 1 or 2; and when n=1, X represents an ether bond, an ester bond, or an amide bond, and when n=2, X represents a nitrogen atom or an amide bond.

Examples of the compound in the second aspect include the following compounds.

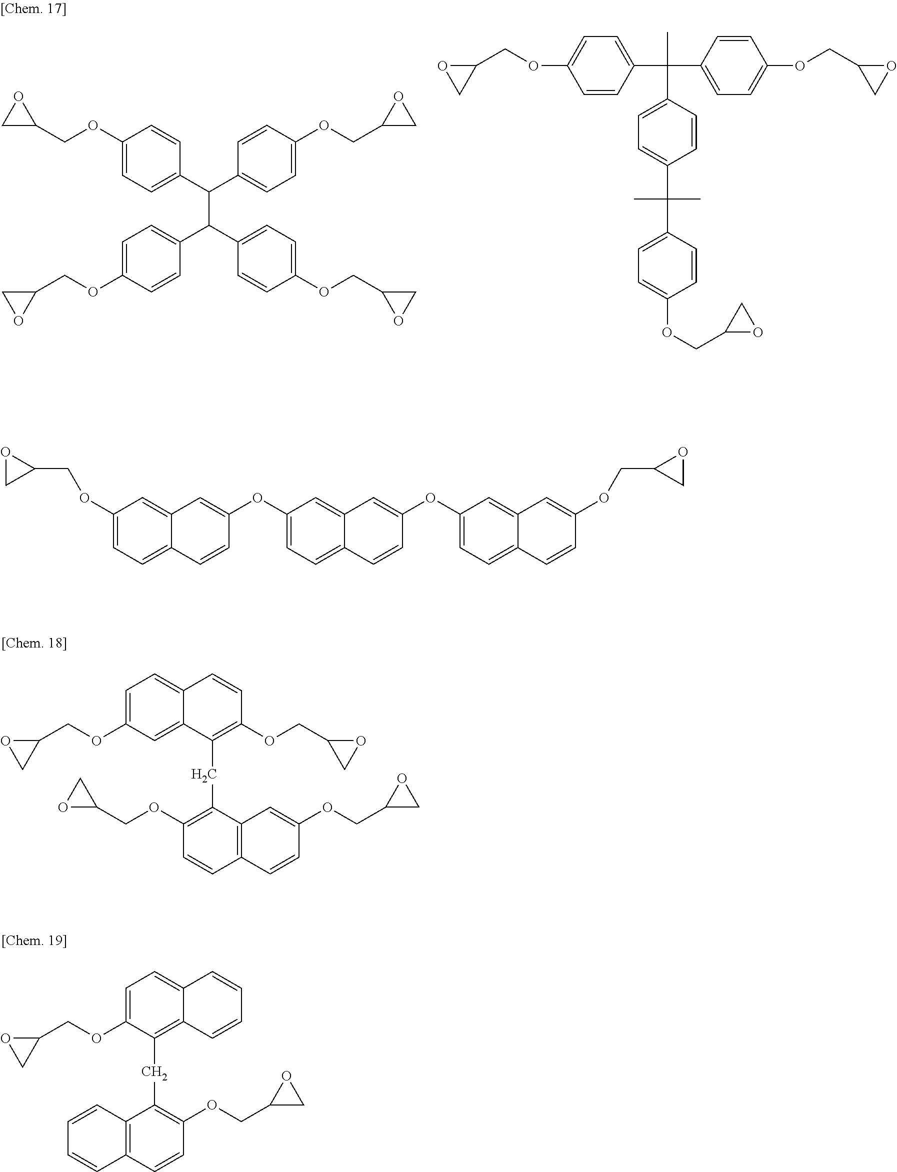 [SMILES: c1cc(C(c2ccc(OCC3CO3)cc2)C(c2ccc(OCC3CO3)cc2)c2ccc(OCC3CO3)cc2)ccc1OCC1CO1 ; CC(C)(c1ccc(OCC2CO2)cc1)c1ccc(C(C)(c2ccc(OCC3CO3)cc2)c2ccc(OCC3CO3)cc2)cc1 ; c1cc2ccc(Oc3ccc4ccc(Oc5ccc6ccc(OCC7CO7)cc6c5)cc4c3)cc2cc1OCC1CO1 ; c1cc2ccc(OCC3CO3)c(Cc3c(OCC4CO4)ccc4ccc(OCC5CO5)cc34)c2cc1OCC1CO1 ; c1ccc2c(Cc3c(OCC4CO4)ccc4ccccc34)c(OCC3CO3)ccc2c1]

### <(B) Compound Having Thiol Structure>

The component (B) used in the present invention is a compound having a thiol structure.

Examples of the compound having a thiol structure according to the present invention include a polyfunctional thiol compound represented by the following Formula (10-1).

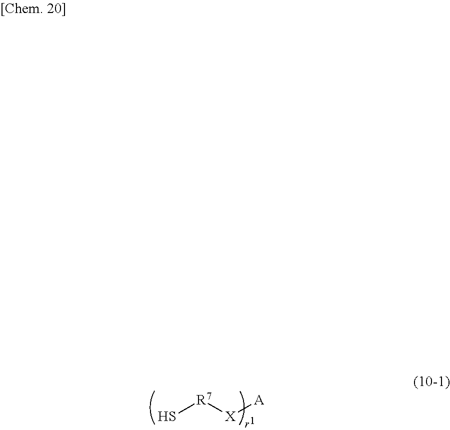

In Formula (10-1), R⁷ represents a single bond or a linear or branched alkylene group having 1 to 6 carbon atoms, X represents a single bond or an ester bond, A represents an organic group having 2 to 12 carbon atoms or a heteroatom, and r¹ represents an integer of 2 to 6.

A may contain at least one heteroatom, or may not contain any heteroatom.

Examples of the heteroatom in A include an oxygen atom and a nitrogen atom.

Examples of the polyfunctional thiol compound represented by the above Formula (10-1) include 1,2-ethanedithiol, 1,3-propanedithiol, bis(2-mercaptoethyl)ether, trimethylolpropane tris(3-mercaptopropionate), tris-[(3-mercaptopropionyloxy)-ethyl]-isocyanurate, tetraethylene glycol bis(3-mercaptopropionate), dipentaerythritol hexakis(3-mercaptopropionate), pentaerythritol tetrakis(3-mercaptobutyrate), 1,4-bis(3-mercaptobutyryloxy)butane, 1,3,5-tris(3-mercaptobutyryloxyethyl)-1,3,5-triazine-2,4,6-(1H,3H,5H)-trione, trimethylolpropane tris(3-mercaptobutyrate), trimethylolethane tris(3-mercaptobutyrate), and pentaerythritol tris(3-mercaptopropyl)ether.

As the polyfunctional thiol compound registered by the following Formula (10-1), commercially available products such as Karenz MT (registered trademark) PE1, Karenz MT NR1, Karenz MT BD1, TPMB, and TEMB (all manufactured by Showa Denko K.K.), and TMMP, TEMPIC, PEMP, EGMP-4, DPMP, TMMP II-20P, PEMP II-20P, and PEPT (all manufactured by SC Organic Chemical Co., Ltd.) can be adopted.

Examples of the polyfunctional thiol compound represented by Formula (10-1) include the following compounds.

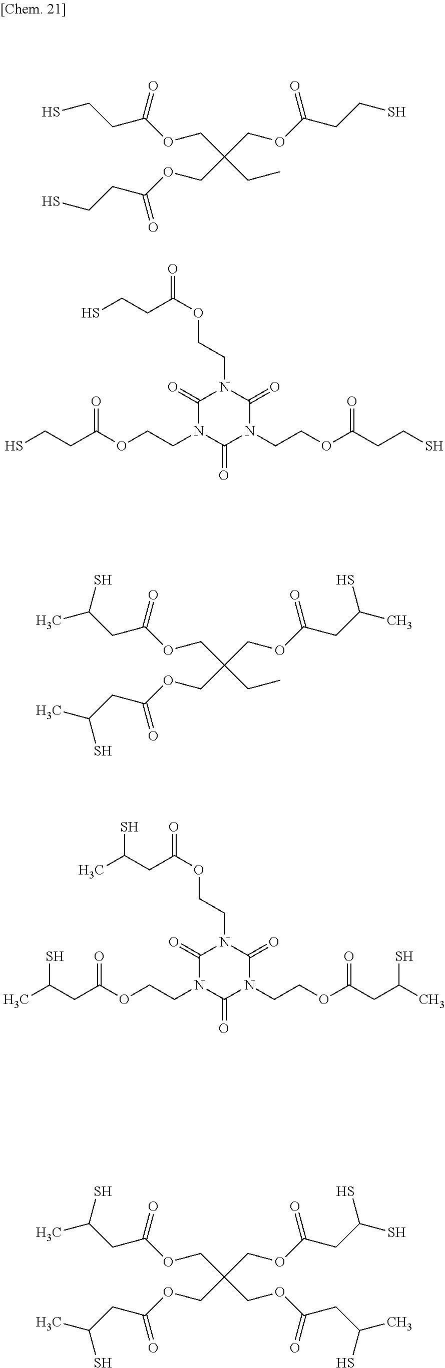

As a content of the compound (B) having a thiol structure in the protective-film forming composition of the present invention, for example, a lower limit of the content thereof is usually 1 mass %, and preferably 5 mass %, with respect to the total solid content of the protective-film forming composition, and an upper limit of the content thereof is usually 70 mass %, preferably 50 mass %, and still more preferably 30 mass %, with respect to the total solid content of the protective-film forming composition.

### <(C) Solvent>

The protective-film forming composition of the present invention can be prepared by dissolving the respective components described above in a solvent, preferably in an organic solvent, and is used in a uniform solution state. Note that, in the present invention, the solvent (C) is different from a compound represented by (F) described later.

The organic solvent for the protective-film forming composition according to the present invention can be used without particular limitation as long as it is an organic solvent capable of dissolving solid components such as the compound or polymer (A), the compound (B) having a thiol structure, and other optional solid components. In particular, since the protective-film forming composition according to the present invention is used in a uniform solution state, it is recommended to use an organic solvent generally used in a lithography process in combination in consideration of application performance thereof.

Examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monoethyl ether, propylene glycol monomethyl ether, propylene glycol monomethyl ether acetate, propropylene glycol propyl ether acetate, toluene, xylene, methyl ethyl ketone, methyl isobutyl ketone, cyclopentanone, cyclohexanone, cycloheptanone, 4-methyl-2-pentanol, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, 2-heptanone, methoxycyclopentane, anisole, γ-butyrolactone, N-methylpyrrolidone, N,N-dimethylformamide, and N,N-dimethylacetamide. One of these solvents can be used alone, or two or more of these solvents can be used in combination.

Among these solvents, propylene glycol monomethyl ether, propylene glycol monomethyl ether acetate, cyclohexanone, and the like are preferable. In particular, propylene glycol monomethyl ether and propylene glycol monomethyl ether acetate are preferable.

A solid content of the protective-film forming composition according to the present invention is usually 0.1 to 70 mass %, and preferably 0.1 to 60 mass %. The solid content is a content ratio of all components excluding the solvent from the protective-film forming composition. A ratio of the compound or polymer (A) in the solid content is preferably 1 to 100 mass %, more preferably 1 to 99.9 mass %, still more preferably 50 to 99.9 mass %, further still more preferably 50 to 95 mass %, and particularly preferably 50 to 90 mass %.

### <(D) Curing Agent>

The component (D) used in the present invention is a curing agent.

The curing agent is not particularly limited as long as an epoxy group of the component (A) can be undergone a crosslinking reaction, and examples thereof include a base, a thermal acid generator, a phenolic curing agent, an amide-based curing agent, an amine-based curing agent, imidazoles, an acid anhydride-based curing agent, organophosphines, a mercaptan-based curing agent, a tertiary amine, a phosphonium salt, a tetraphenylboron salt, an organic acid dihydrazide, a halogenated boroamine complex, an isocyanate-based curing agent, and a blocked isocyanate-based curing agent.

Note that, for example, 2-phenylimidazole is a base and also imidazoles. As described above, in the present invention, there may be specific examples belonging to a plurality of types of subordinate concepts of the curing agents exemplified above.

### <<Base>>

Examples of the base include imidazole-based compounds (a piperidine compound, an amide-based compound, an amine-based compound, a diazabicycloundecene (DBU)-based compound, a diazabicyclononene (DBN)-based compound, a phosphonium-based compound, and a urea-based compound). Among them, an imidazole-based compound is preferable from the viewpoint of storage stability.

The base used in the present invention may also include an aspect constituting a salt with an acid.

For example, an imidazole-based compound will be described below as an example.

Examples of the base of the component (B) referred to in the present invention include (i) an imidazole-based compound represented by the following Formula (B1), (ii) a salt of an imidazole-based compound represented by Formula (B1) and an acid, and (iii) a quaternary salt containing a cation represented by the following Formula (B2).

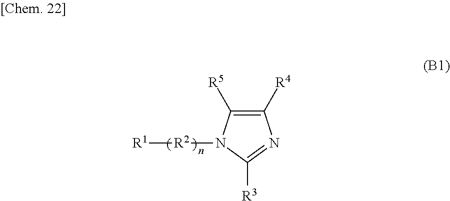

In Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or less carbon atoms, which may be substituted, R⁵ represents a hydrogen atom, a formyl group, an alkyl group having 1 to 4 carbon atoms, which may be substituted, or an alkoxyalkyl group having 4 or less carbon atoms, which may be substituted, and n represents 0 or 1.

Examples of the substituents in the aryl group which may be substituted and the triazine ring which may be substituted include an amino group and a hydroxy group.

The alkyl group may be either linear or branched.

Examples of the aryl group include a phenyl group, a naphthyl group, a biphenyl group, and an anthryl group.

In R⁴ or R⁵, examples of the substituents in the alkyl group which may be substituted and the alkoxyalkyl group which may be substituted include a hydroxy group and a cyano group.

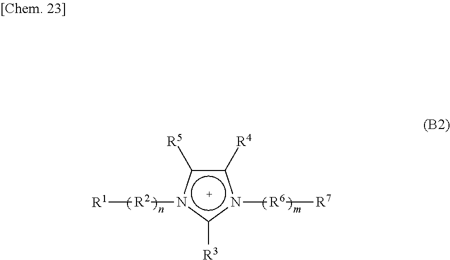

In Formula (B2), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or less carbon atoms, which may be substituted, R⁵ represents a hydrogen atom, a formyl group, an alkyl group having 1 to 4 carbon atoms, which may be substituted, or an alkoxyalkyl group having 4 or less carbon atoms, which may be substituted, R⁶ represents an alkylene group having 1 to 4 carbon atoms, R⁷ represents an alkyl group having 1 to 4 carbon atoms or an aryl group which may be substituted, m represents 0 or 1, and n represents 0 or 1.

In Formula (B2), the descriptions of R¹ to R⁵ are the same as in Formula (B1). In addition, in Formula (B2), examples of the substituent in the aryl group which may be substituted of R⁷ include an amino group and a hydroxy group. Specific examples of the aryl group of R⁷ include those described above.

In a case where the base of the component (B) referred to in the present invention forms a salt with a pair of anions as described above, the pair of anions are not particularly limited, and examples thereof include imide, halogen, carboxylate, sulfate, sulfonate, thiocyanate, aluminate, borate, phosphate, phosphinate, amide, antimonate, and methide, and more specifically include (CF₃SO₂)₂N⁻, (CF₃SO₂)(FSO₂)N⁻, (FSO₂)₂N⁻, (CF₃CF₂SO₂)₂N⁻, (CN)₂N⁻, OH⁻, Cl⁻, Br⁻, I⁻, NO₃⁻, CH₃COO⁻, CF₃COO⁻, CF₃CF₂CF₂COO⁻, CF₃SO₃⁻, CF₃CF₂SO₃⁻, CF₃CF₂CF₂CF₂SO₃⁻, SbF₆⁻, AlCl₄⁻, SCN⁻, PF₆⁻, BF₄⁻, [CF₃OCF₂CF₂BF₃⁻], and [(CₚF₂ₚ₊₂)BF₃]⁻ (p represents an integer of 1, 2, 3, or 4).

Furthermore, examples thereof include anions represented by the following.

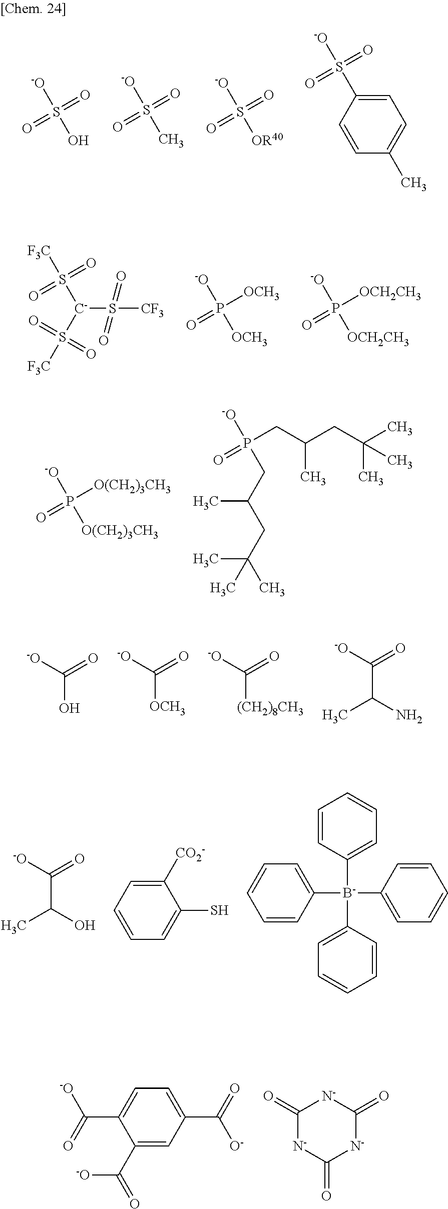

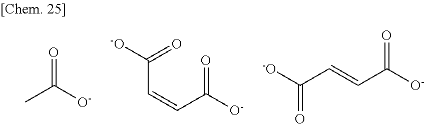

In the formula, R⁴⁰ represents an alkyl group having 1 to 10 carbon atoms.

The base used in the present invention is specifically shown below by taking an imidazole-based compound as an example, but is not limited thereto.

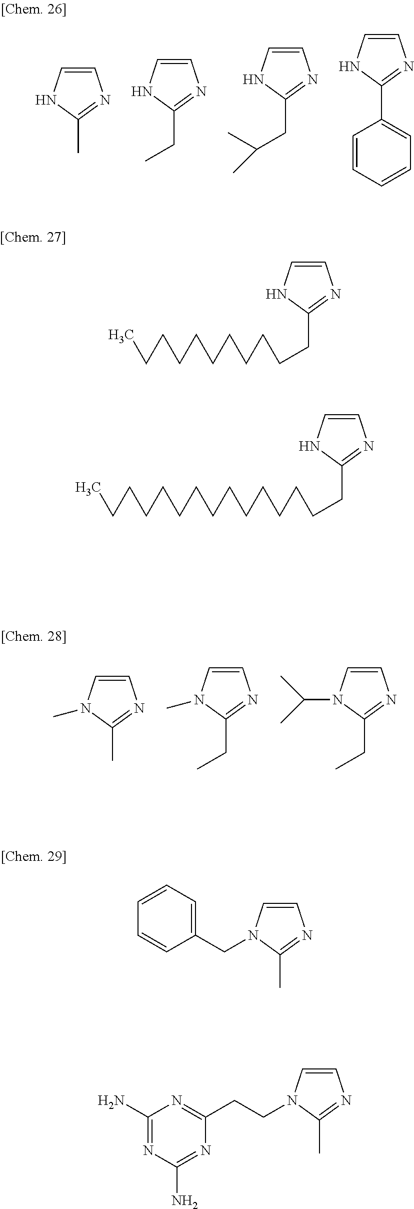

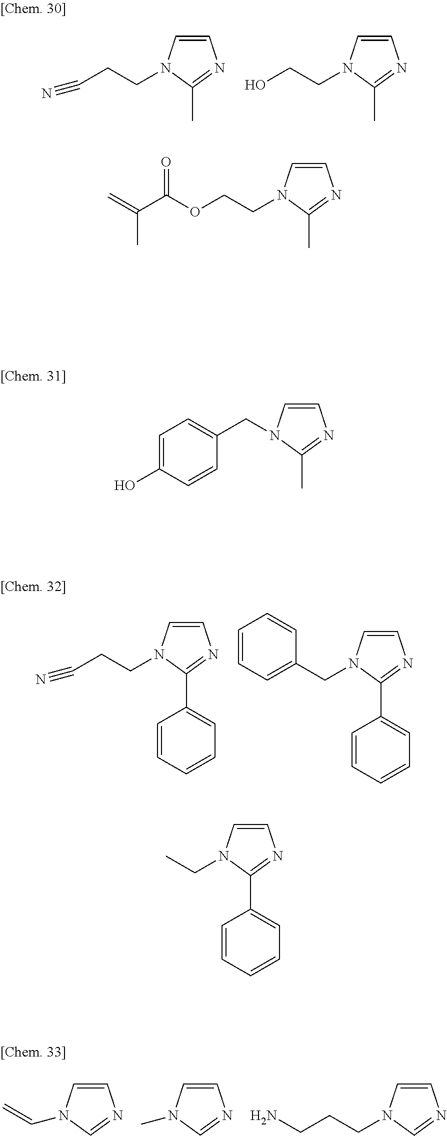

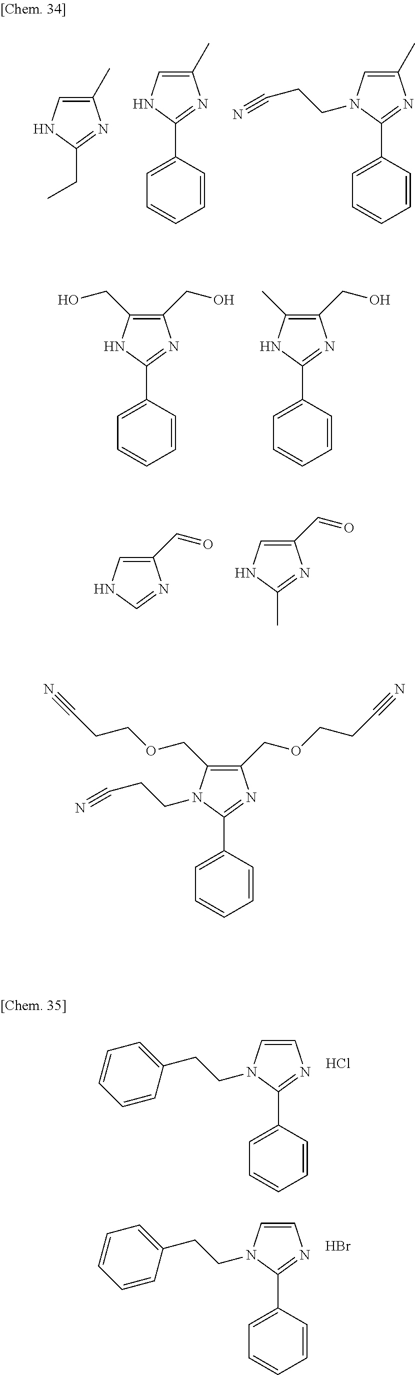

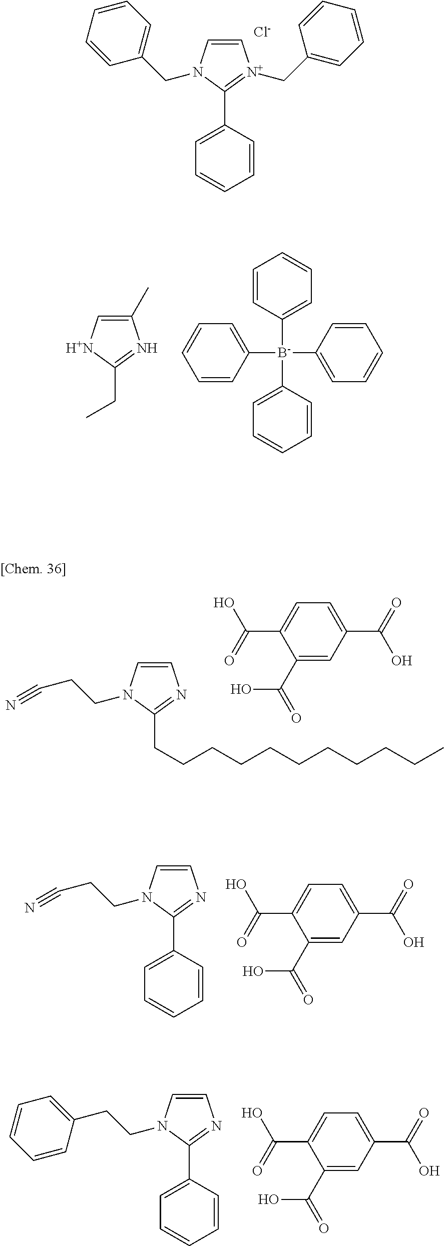

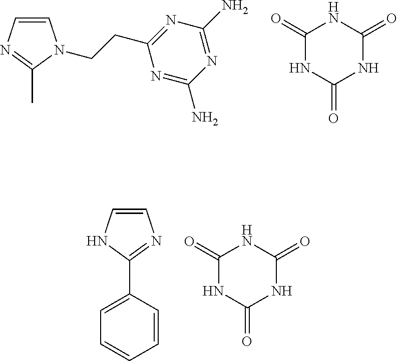

### <<Thermal Acid Generator>

Examples of the thermal acid generator include pyridinium p-toluenesulfonate, pyridinium trifluoromethanesulfonate, pyridinium p-phenolsulfonate, K-PURE [registered trademark] CXC-1612, CXC-1614, TAG-2172, TAG-2179, TAG-2678, TAG2689 (all manufactured by King Industries, Inc.), and SI-45, SI-60, SI-80, SI-100, SI-110, and SI-150 (all manufactured by Sanshin Chemical Industry Co., Ltd.).

### <<Phenolic Curing Agent>>

Examples of the phenolic curing agent include bisphenol A, bisphenol F, 4,4′-dihydroxydiphenylmethane, 4,4′-dihydroxydiphenyl ether, 1,4-bis(4-hydroxyphenoxy)benzene, 1,3-bis(4-hydroxyphenoxy)benzene, 4,4′-dihydroxydiphenyl sulfide, 4,4′-dihydroxydiphenyl ketone, 4,4′-dihydroxydiphenyl sulfone, 4,4′-dihydroxybiphenyl, 2,2′-dihydroxybiphenyl, 10-(2,5-dihydroxyphenyl)-10H-9-oxa-10-phosphaphenanthrene-10-oxide, phenol novolac, bisphenol A novolac, o-cresol novolac, m-cresol novolac, p-cresol novolac, xylenol novolac, poly-p-hydroxystyrene, hydroquinone, resorcinol, catechol, t-butylcatechol, t-butylhydroquinone, fluoroglycinol, pyrogallol, t-butylpyrogallol, allylated pyrogallol, polyallylated pyrogallol, 1,2,4-benzenetriol, 2,3,4-trihydroxybenzophenone, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,4-dihydroxynaphthalene, 2,5-dihydroxynaphthalene, 2,6-dihydroxynaphthalene, 2,7-dihydroxynaphthalene, 2,8-dihydroxynaphthalene, an allylated or polyallylated compound of the dihydroxynaphthalene, allylated bisphenol A, allylated bisphenol F, allylated phenol novolac, and allylated pyrogallol.

### <<Amine-Based Curing Agent>>

Examples of the amine-based curing agent include aliphatic amines, polyether amines, alicyclic amines, and aromatic amines.

Examples of the aliphatic amines include ethylenediamine, 1,3-diaminopropane, 1,4-diaminopropane, hexamethylenediamine, 2,5-dimethyl hexamethylenediamine, trimethylhexamethylenediamine, diethylenetriamine, iminobispropylamine, bis(hexamethylene)triamine, triethylenetetramine, tetraethylenepentamine, pentaethylenehexamine, N-hydroxyethyl ethylenediamine, and tetra(hydroxyethyl)ethylenediamine.

Examples of the polyether amines include triethylene glycol diamine, tetraethylene glycol diamine, diethylene glycol bis(propylamine), polyoxypropylene diamine, and polyoxypropylene triamines.

Examples of the alicyclic amines include isophoronediamine, methacenediamine, N-aminoethylpiperazine, bis(4-amino-3-methyldicyclohexyl)methane, bis(aminomethyl)cyclohexane, 3,9-bis(3-aminopropyl)-2,4,8,10-tetraoxaspiro(5,5)undecane, and norbornene diamine.

Examples of the aromatic amines include tetrachloro-p-xylenediamine, m-xylenediamine, p-xylenediamine, m-phenylenediamine, o-phenylenediamine, p-phenylenediamine, 2,4-diaminoanisole, 2,4-toluenediamine, 2,4-diaminodiphenylmethane, 4,4′-diaminodiphenylmethane, 4,4′-diamino-1,2-diphenylethane, 2,4-diaminodiphenylsulfone, 4,4′-diaminodiphenylsulfone, m-aminophenol, m-aminobenzylamine, benzyldimethylamine, 2-dimethylaminomethyl)phenol, triethanolamine, methylbenzylamine, α-(m-aminophenyl)ethylamine, α-(p-aminophenyl)ethylamine, diaminodiethyldimethyldiphenylmethane, and α,α′-bis(4-aminophenyl)-p-diisopropylbenzene.

### <<Imidazoles>>

Examples of the imidazoles include 2-phenylimidazole, 2-ethyl-4(5)-methylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, a 2,4-diamino-6-[2′-methylimidazolyl-(1′)]-ethyl-s-triazine isocyanuric acid adduct, a 2-phenylimidazole isocyanuric acid adduct, 2-phenyl-4,5-dihydroxymethylimidazole, 2-phenyl-4-methyl-5-hydroxymethylimidazole, and an adduct of the imidazoles with an epoxy resin.

### <<Acid Anhydride-Based Curing Agent>>

Examples of the acid anhydride-based curing agent include an acid anhydride and a modified product of an acid anhydride.

Examples of the acid anhydride include phthalic anhydride, trimellitic anhydride, pyromellitic anhydride, benzophenone tetracarboxylic anhydride, dodecenyl succinic anhydride, polyadipic anhydride, polyazelaic anhydride, polysebacic anhydride, poly(ethyl octadecanedioic acid) anhydride, poly(phenyl hexadecanedioic acid) anhydride, tetrahydrophthalic anhydride, methyltetrahydrophthalic anhydride, methylhexahydrophthalic anhydride, hexahydrophthalic anhydride, methylhymic anhydride, tetrahydrophthalic anhydride, trialkyltetrahydrophthalic anhydride, methylcyclohexene dicarboxylic anhydride, methylcyclohexene tetracarboxylic anhydride, ethylene glycol bistrimellitate dianhydride, HET anhydride, nadic anhydride, methylnadic anhydride, 5-(2,5-dioxotetrahydro-3-furanyl)-3-methyl-3-cyclohexane-1,2-dicarboxylic anhydride, 3,4-dicarboxy-1,2,3,4-tetrahydro-1-naphthalene succinic dianhydride, and 1-methyl-dicarboxy-1,2,3,4-tetrahydro-1-naphthalene succinic dianhydride.

Examples of the modified product of the acid anhydride include a product obtained by modifying the acid anhydride with a glycol. Here, examples of the glycol that can be used for modification include alkylene glycols such as ethylene glycol, propylene glycol, and neopentyl glycol, and polyether glycols such as polyethylene glycol, polypropylene glycol, and polytetramethylene ether glycol. Furthermore, copolymerized polyether glycols of two or more kinds of these glycols and/or polyether glycols can also be used. Note that, in the modified product of the acid anhydride, it is preferable to modify the acid anhydride in an amount of 0.4 mol or less of glycol with respect to 1 mol of the acid anhydride.

<<Organophosphines>>

Examples of the organophosphines include tributylphosphine, methyldiphenylphosphine, triphenylphosphine, diphenylphosphine, and phenylphosphine.

### <<Phosphonium Salt>>

Examples of the phosphonium salt include tetraphenylphosphonium tetraphenylborate, tetraphenylphosphonium ethyltriphenylborate, and tetrabutylphosphonium tetrabutylborate.

### <<Tetraphenylboron Salt>>

Examples of the tetraphenylboron salt include 2-ethyl-4-methylimidazole tetraphenylborate and N-methylmorpholine tetraphenylborate.

As a content of the curing agent (D) in the protective-film forming composition of the present invention, for example, a lower limit of the content thereof is usually 0.0001 mass %, preferably 0.01 mass %, and more preferably 0.1 mass %, with respect to the total solid content of the protective-film forming composition, and an upper limit of the content thereof is usually 50 mass %, preferably 40 mass %, and more preferably 30 mass %, with respect to the total solid content of the protective-film forming composition.

### <(E) Compound or Polymer Having Phenolic Hydroxy Group>

The protective-film forming composition of the present invention may further contain (E) a compound or polymer having a phenolic hydroxy group.

The compound or polymer having a phenolic hydroxy group (E) is not particularly limited as long as it is a compound or polymer that does not impair the effect of the present invention. Needless to say, the compound or polymer having a phenolic hydroxy group (E) is different from the compound or polymer (A).

A weight-average molecular weight of the compound or polymer having a phenolic hydroxy group (E) (hereinafter, also referred to as (E) a compound or polymer) is also not particularly limited, and is, for example, 300 to 50,000.

The compound or polymer (E) preferably has two or more phenolic hydroxy groups.

More preferred embodiments of the compound or polymer (E) include, for example, compounds or polymers shown in the following third to fifth aspects.

### <<Third Aspect>>

Examples of the compound or polymer (E) used in the present invention include a compound or polymer represented by (Formula 2-1).

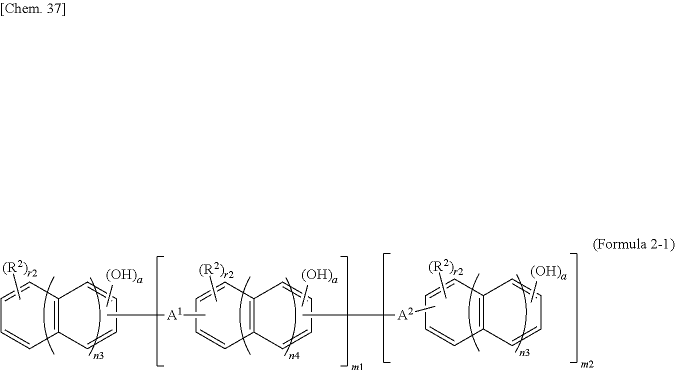

In the formula, R²'s each independently represent a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group. A¹ and A² each independently represent an alkylene group having 1 to 10 carbon atoms, a divalent organic group derived from a bicyclo ring compound, a biphenylene group, a divalent organic group represented by —C(T²)(T³)-, or a combination thereof, T² represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group, and T³ represents a hydrogen atom or a monovalent group represented by (Formula 2-1-a).

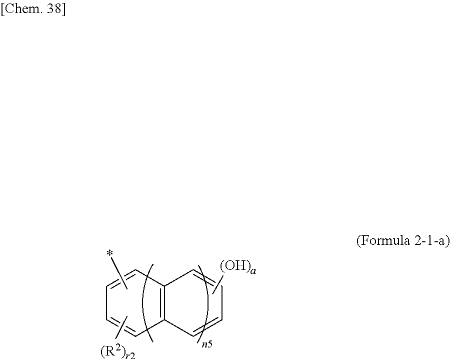

In (Formula 2-1-a), * represents a binding site to a carbon atom to which T³ is bonded. R² has the same meaning as R² in (Formula 2-1). a represents an integer of 1 to 6. n3 to n5 each independently represent an integer of 0 to 2. r2 represents an integer of 0 to 3. m1 and m2 each independently represent 0 to 10,000,000.

It is preferable that m1, n3 to n5, and r2 are 0, and m2 is 1.

The descriptions of the halogeno group, the alkoxy group, and the alkyl group according to (Formula 2-1) are as described above.

Examples of the bicyclo ring compound include dicyclopentadiene, substituted dicyclopentadiene, tetracyclo[4.4.0.12,5.17,10]dodeca-3,8-diene, and substituted tetracyclo[4.4.0.12,5.17,10]dodeca-3,8-diene. Substitution means that one or two or more hydrogen atoms of the bicyclo ring compound are each independently substituted with a halogeno group, a nitro group, an amino group or a hydroxy group, or an alkyl group having 1 to 10 carbon atoms or an aryl group having 6 to 40 carbon atoms, which may be substituted with these groups. The divalent organic group derived from the bicyclo ring compound refers to a group having two bonds which is derived by removing any two hydrogen atoms from the bicyclo ring compound.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Specific examples of the compound represented by (Formula 2-1) include the following compounds.

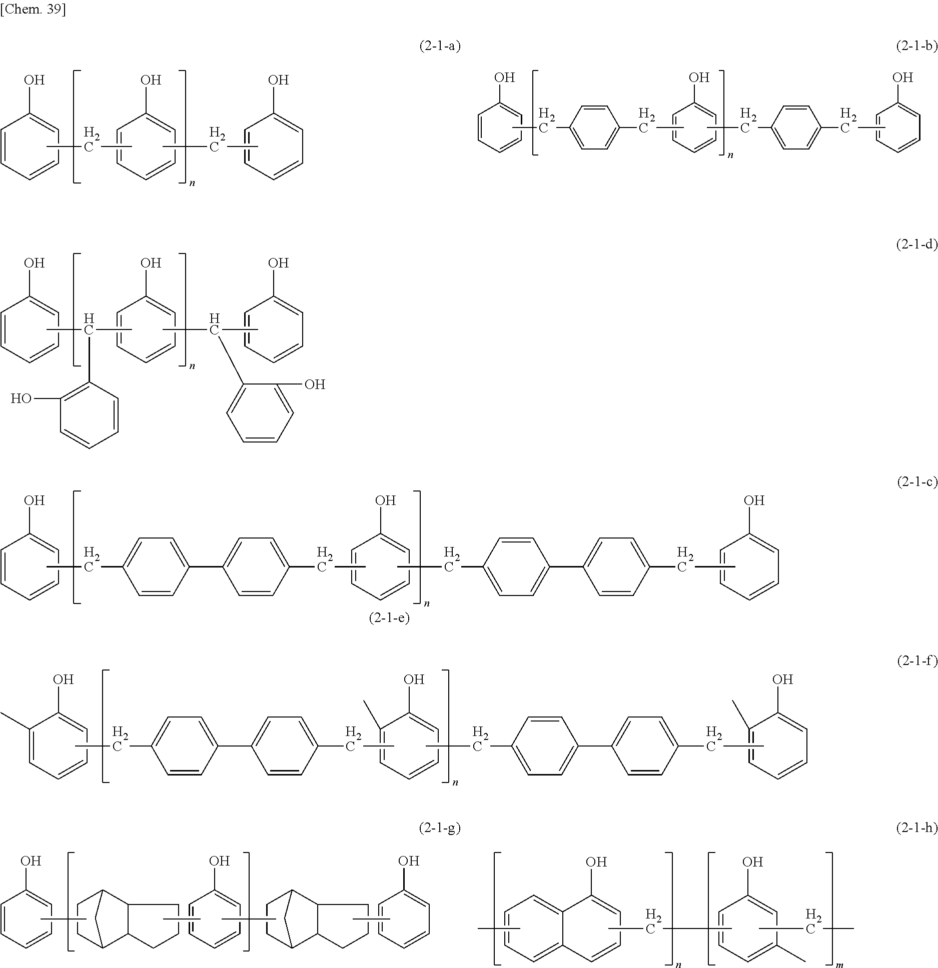

The compound or polymer (E) may be a compound shown below.

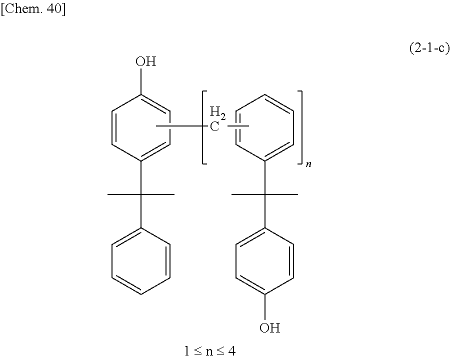

### <<Fourth Aspect>>

Examples of the compound or polymer (E) used in the present invention include a compound represented by (Formula 2-2).

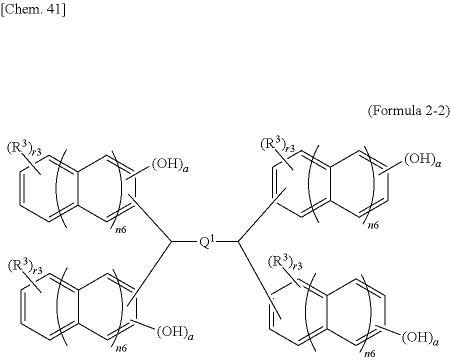

In the formula, R³ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group. Q¹ represents a single bond, an oxygen atom, a sulfur atom, a sulfonyl group, a carbonyl group, an imino group, an arylene group having 6 to 40 carbon atoms, or an alkylene group having 1 to 10 carbon atoms, which may be substituted with a halogeno group. a represents an integer of 1 to 6. n6 represents an integer of 0 to 2. r3 represents an integer of 0 to 3.

The descriptions of the alkoxy group, the alkyl group, and the halogeno group of (Formula 2-2) are as described above.

Examples of the arylene group having 6 to 40 carbon atoms include a phenylene group, an o-methylphenylene group, an m-methylphenylene group, a p-methylphenylene group, an o-chlorophenylene group, an m-chlorophenylene group, a p-chlorophenylene group, an o-chlorophenylene group, a p-fluorophenylene group, an o-methoxyphenylene group, a p-methoxyphenylene group, a p-nitrophenylene group, a p-cyanophenylene group, an α-naphthylene group, a β-naphthylene group, an o-biphenylylene group, an m-biphenylylene group, a p-biphenylylene group, a 1-anthrylene group, a 2-anthrylene group, a 9-anthrylene group, a 1-phenanthrylene group, a 2-phenanthrylene group, a 3-phenanthrylene group, a 4-phenanthrylene group, and a 9-phenanthrylene group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

Specific examples of the compound represented by (Formula 2-2) include the following compounds.

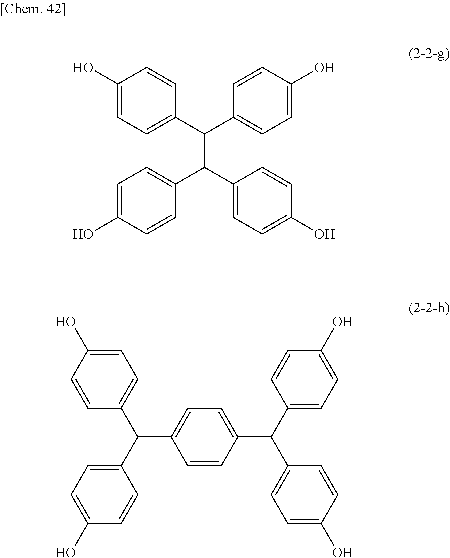 [SMILES: Oc1ccc(C(c2ccc(O)cc2)C(c2ccc(O)cc2)c2ccc(O)cc2)cc1 ; Oc1ccc(C(c2ccc(O)cc2)c2ccc(C(c3ccc(O)cc3)c3ccc(O)cc3)cc2)cc1]

The compound (E) may be a compound represented by the following Formula (4-1).

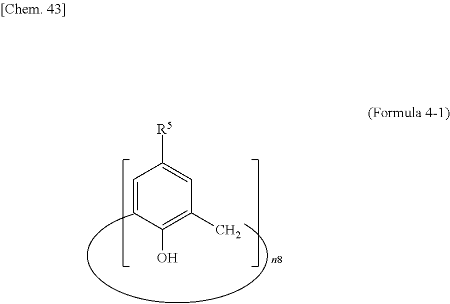

In Formula, R⁵ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group. In the formula, n8 represents an integer of 4, 5, 6, or 8. The descriptions of the terms are as described above.

Specific examples of the compound represented by Formula (4-1) are shown below.

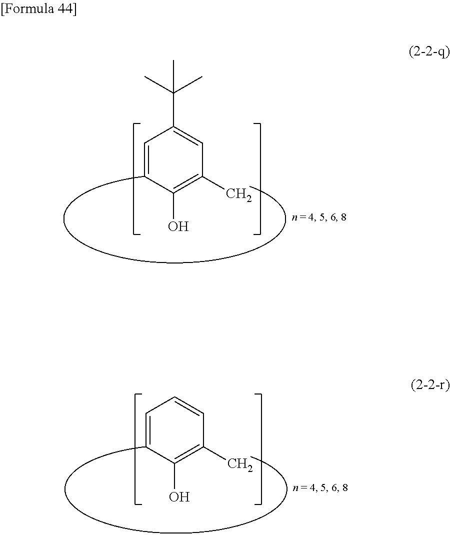

The compound (E) may be compounds represented by the following Formulas (5-1) and (5-1-a).

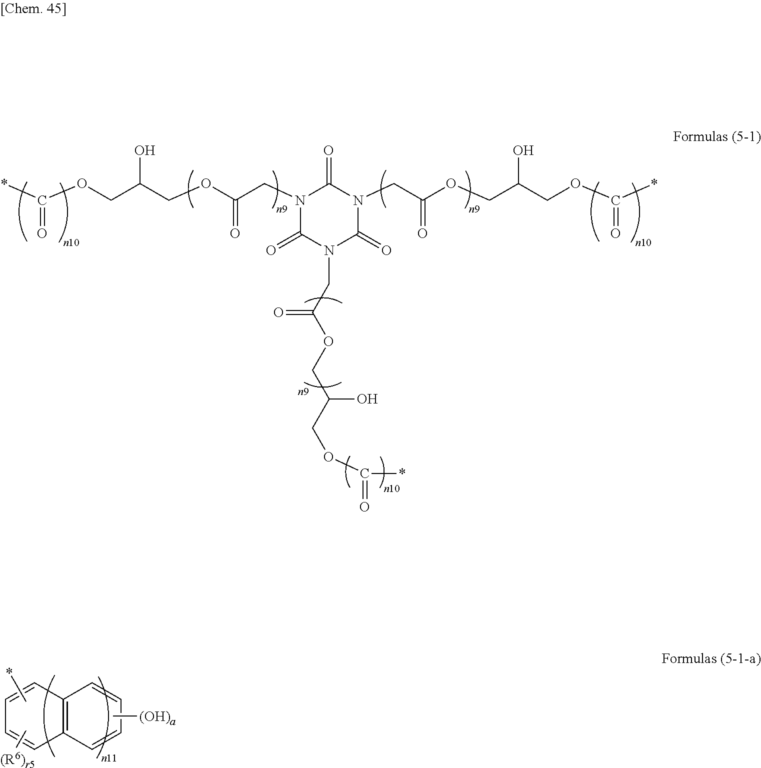

In the formula, n9 and n10 each represent an integer of 0 or 1, R⁶ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group. a represents an integer of 1 to 6. n11 represents an integer of 1 or 2. r5 represents an integer of 0 to 3. * represents a binding site between the structure represented by Formula (5-1) and the structure represented by Formula (5-1-a).

The descriptions of the terms are as described above.

Specific examples of the compounds represented by Formula (5-1) and Formula (5-1-a) are shown below.

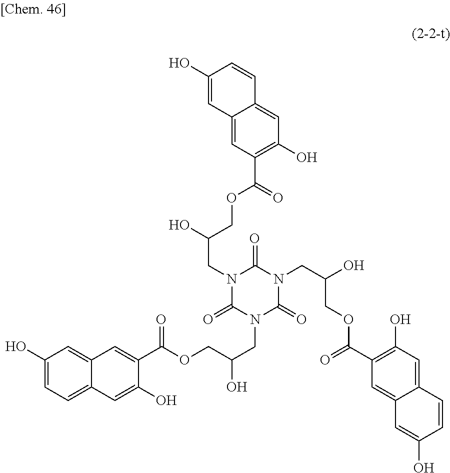 [SMILES: O=C(OCC(O)Cn1c(=O)n(CC(O)COC(=O)c2cc3cc(O)ccc3cc2O)c(=O)n(CC(O)COC(=O)c2cc3cc(O)ccc3cc2O)c1=O)c1cc2cc(O)ccc2cc1O]

The compound (E) may be a compound shown below.

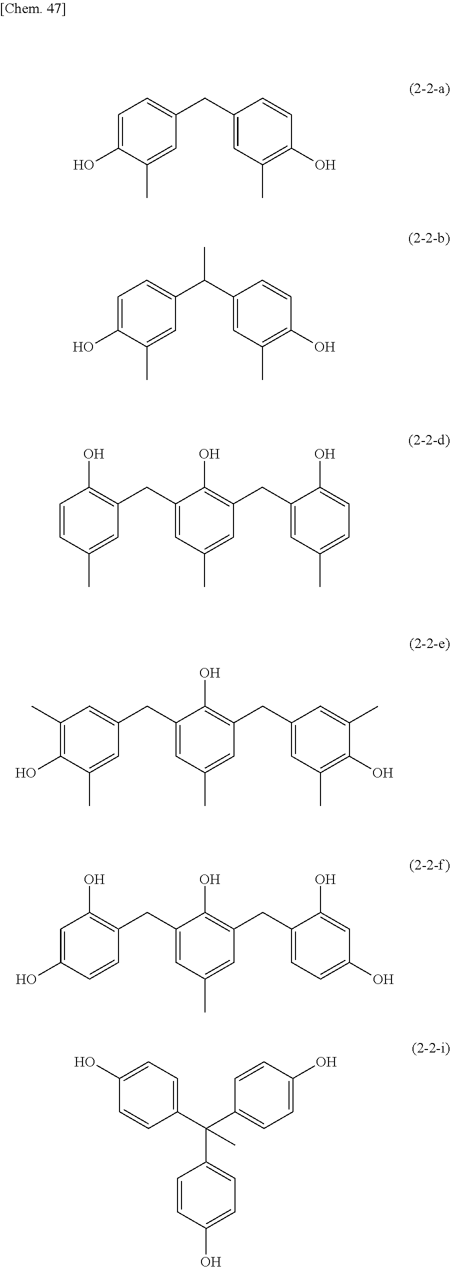 [SMILES: Cc1cc(Cc2ccc(O)c(C)c2)ccc1O ; Cc1cc(C(C)c2ccc(O)c(C)c2)ccc1O ; Cc1ccc(O)c(Cc2cc(C)cc(Cc3cc(C)ccc3O)c2O)c1 ; Cc1cc(Cc2cc(C)c(O)c(C)c2)c(O)c(Cc2cc(C)c(O)c(C)c2)c1 ; Cc1cc(Cc2ccc(O)cc2O)c(O)c(Cc2ccc(O)cc2O)c1 ; CC(c1ccc(O)cc1)(c1ccc(O)cc1)c1ccc(O)cc1]

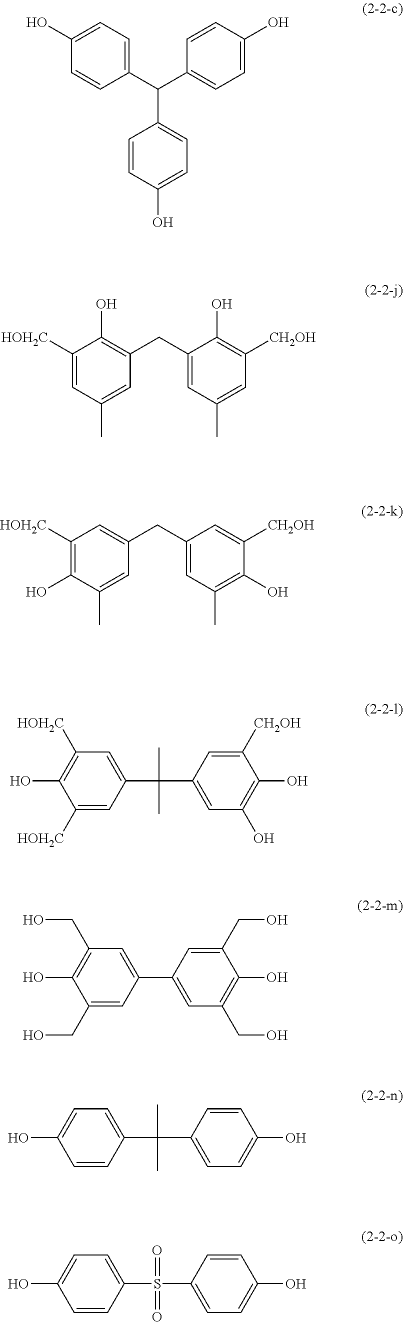

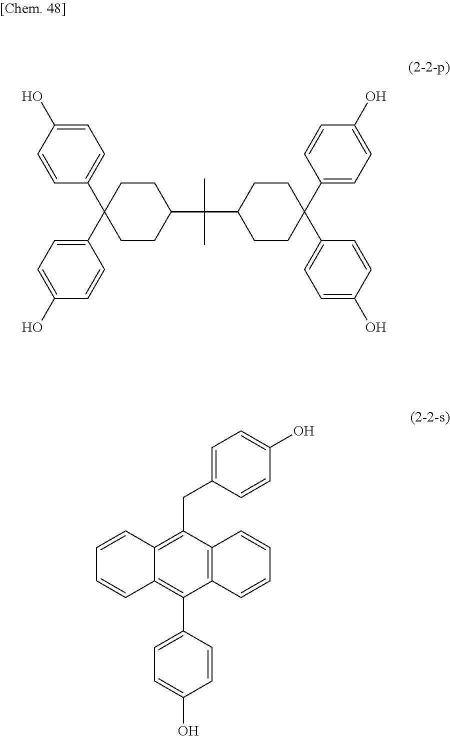 [SMILES: CC(C)(C1CCC(c2ccc(O)cc2)(c2ccc(O)cc2)CC1)C1CCC(c2ccc(O)cc2)(c2ccc(O)cc2)CC1 ; Oc1ccc(Cc2c3ccccc3c(-c3ccc(O)cc3)c3ccccc23)cc1]

### <<Fifth Aspect>>

The compound or polymer (E) used in the present invention is not particularly limited as long as it is a polymer that does not impair the effect of the present invention, and for example, the polymer (E) preferably has at least three or more repeating unit structures.

A weight-average molecular weight of the polymer (E) is not particularly limited, and is, for example, 1,000 to 50,000.

The polymer (E) preferably has a unit structure represented by the following (Formula 3-1).

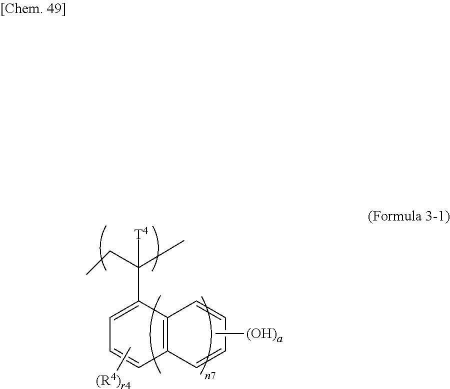

in the formula, T⁴ represents a hydrogen atom or an alkyl group having 1 to 10 carbon atoms, which may be substituted with a halogeno group; R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group; r4 represents an integer of 0 to 3; n7 represents an integer of 0 to 2; and a represents an integer of 1 to 6.

The descriptions of the halogeno group, the alkyl group, and the alkoxy group are as described above.

The polymer represented by (Formula 3-1) may be a polymer having one kind of unit structure represented by (Formula 3-1), or a copolymer having two or more kinds of unit structures represented by (Formula 3-1).

Specific examples of the polymer (E) represented by (Formula 3-1) include polymers having unit structures described below.

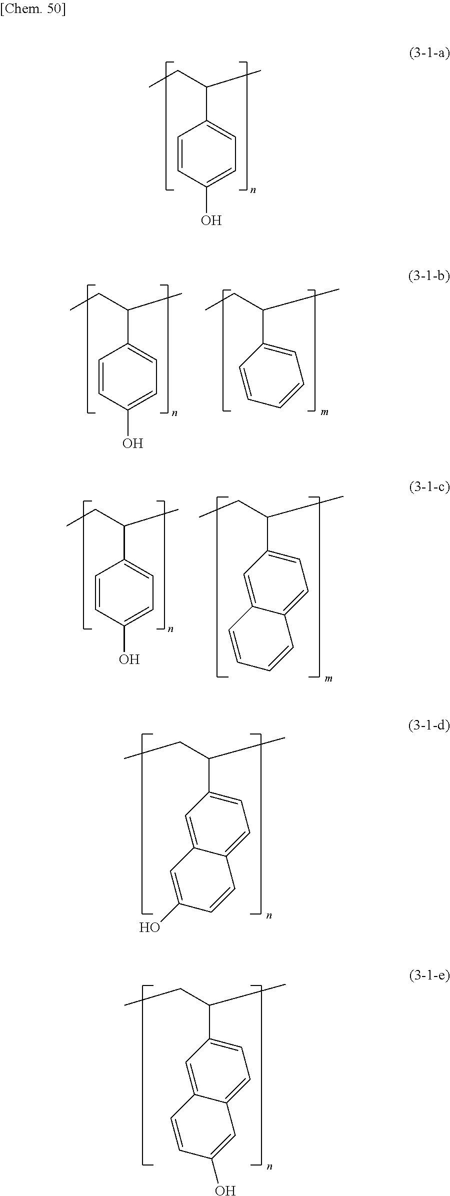

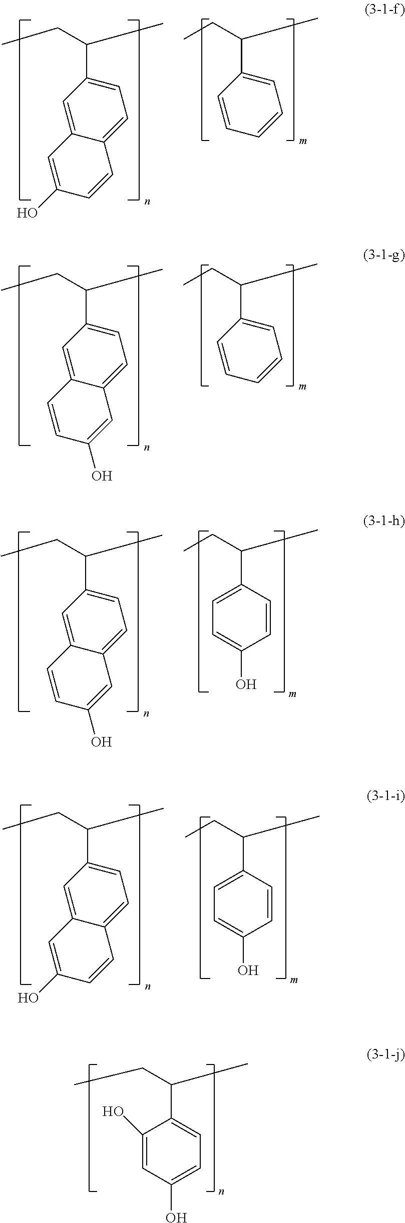

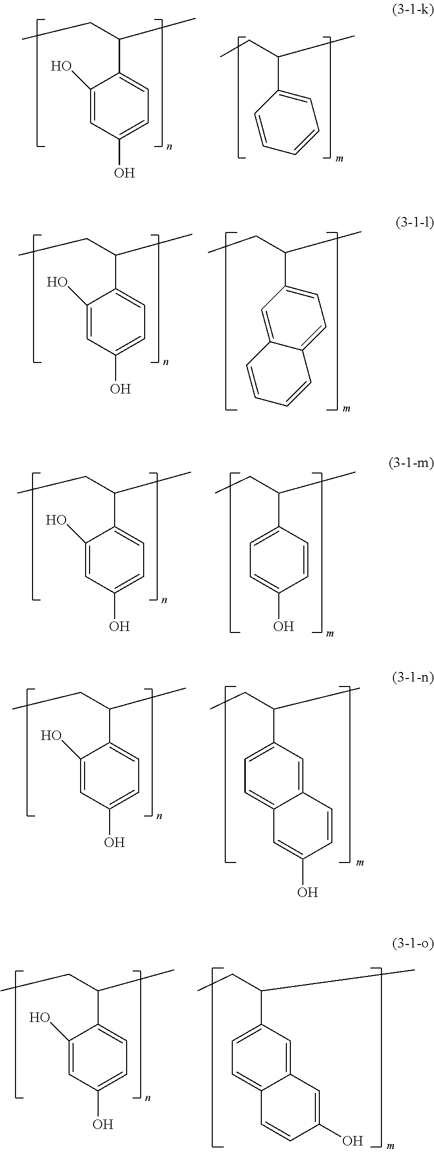

In the above formula, m and n described beside the repeating unit represent a molar ratio of copolymerization.

### <(F) Component>

The protective-film forming composition of the present invention may further contain (F) a compound having a hydroxy group and at least one of a hydroxy group or a carbonyl group (hereinafter, may be referred to as the “compound represented by (F)” or the “compound (F)”).

The number of carbon atoms of the compound (F) is, for example, 2 to 20.

As the compound (F), a compound represented by the following Formula (20-1), a compound represented by the following Formula (20-2), and a compound represented by the following Formula (20-3) are preferable.

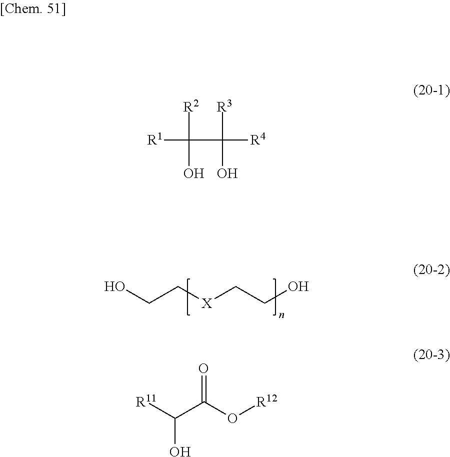

In Formula (20-1), R¹ to R⁴ each independently represent a hydrogen atom, an alkyl group having 1 to 6 carbon atoms, or a hydroxyalkyl group having 1 to 6 carbon atoms.

In Formula (20-2), X represents —O— or —NR— (R represents a hydrogen atom, an alkyl group having 1 to 6 carbon atoms which may have a hydroxy group, an aryl group having 6 to 12 carbon atoms which may have a substituent, or an aralkyl group having 7 to 13 carbon atoms which may have a substituent. n represents an integer of 1 to 3. When n is 2 or 3, X may be the same or different.

In Formula (20-3), R¹¹ represents an alkyl group having 1 to 4 carbon atoms. R¹² represents an alkyl group having 1 to 6 carbon atoms.

The alkyl group and the hydroxyalkyl group in R¹ to R⁴ of Formula (20-1) may be linear, branched, or cyclic, and are preferably linear.

It is preferable that, in Formula (20-1), R¹ to R³ preferably represent a hydrogen atom, and R⁴ represents an alkyl group having 1 to 6 carbon atoms or a hydroxyalkyl group having 1 to 6 carbon atoms.

Examples of the aromatic ring in the aryl group having 6 to 12 carbon atoms, which may have a substituent, include a benzene ring and a naphthalene ring.

Examples of the aromatic ring in the aralkyl group having 7 to 13 carbon atoms, which may have a substituent, include a benzene ring and a naphthalene ring.

Examples of the substituents in the aryl group having 6 to 12 carbon atoms, which may have a substituent, and the aralkyl group having 7 to 13 carbon atoms, which may have a substituent, include an alkyl group having 1 to 6 carbon atoms and an alkoxy group having 1 to 6 carbon atoms.

R in —NR— of Formula (20-2) is preferably an alkyl group having 1 to 6 carbon atoms, which may have a hydroxy group, or an aryl group having 6 to 12 carbon atoms, which may have a substituent. As the alkyl group having 1 to 6 carbon atoms, which may have a hydroxy group, a hydroxyalkyl group is preferable, and a 2-hydroxyethyl group is more preferable.

In Formula (20-2), when X is —O—, n is preferably 2.

In Formula (20-2), when X is —NR—, n is preferably 1.

Examples of the compound (F) include the following compounds.

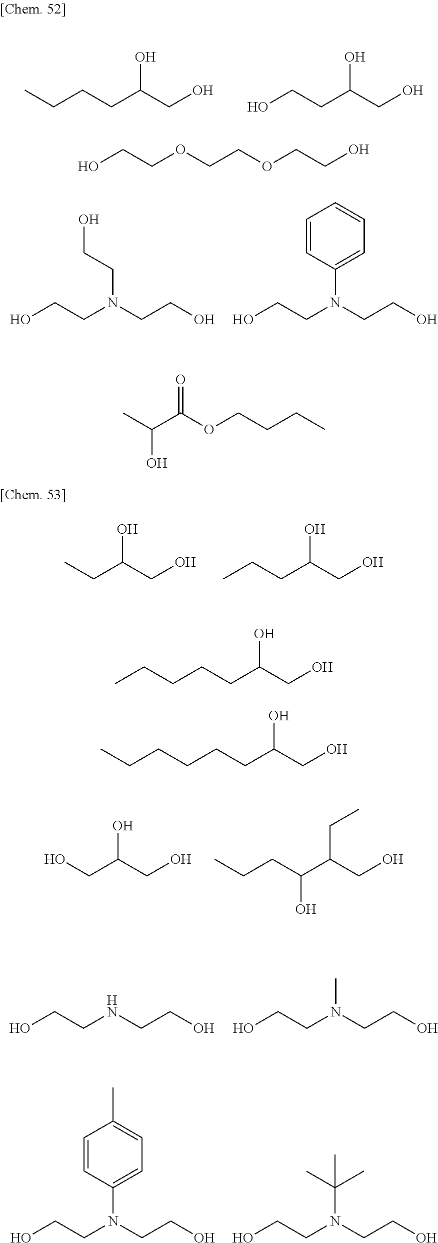

As a content of the compound (F) in the protective-film forming composition of the present invention is not particularly limited, a lower limit of the content thereof is preferably 0.5 mass %, more preferably 1 mass %, and particularly preferably 5 mass %, with respect to the compound or polymer (A), and an upper limit of the content thereof is preferably 50 mass %, more preferably 30 mass %, and particularly preferably 20 mass %, with respect to the compound or polymer (A).

As a content of the compound (F) in the protective-film forming composition of the present invention is not particularly limited, a lower limit of the content thereof is preferably 0.0001 mass %, more preferably 0.005 mass %, and particularly preferably 0.001 mass %, with respect to the solvent (C), and an upper limit of the content thereof is preferably 50 mass %, more preferably 30 mass %, and particularly preferably 20 mass %, with respect to the solvent (C).

### (Resist Underlayer-Film Forming Composition)

A resist underlayer-film forming composition of the present invention contains
(A) a compound or polymer having an epoxy structure represented by the above Formula (I),
(B) a compound having a thiol structure, and
(C) a solvent, and
the above protective-film forming composition of the present invention not only exhibits excellent resistance to a semiconductor wet etching solution, but can also be effectively used as a resist underlayer-film forming composition.

The descriptions of the terms related to the resist underlayer-film forming composition of the present invention are the same as the description contents of the protective-film forming composition.

### (Protective Film, Resist Underlayer Film, Resist-Patterned Substrate, and Method for Manufacturing Semiconductor Device, and the Like)

Hereinafter, a method for manufacturing a resist-patterned substrate and a method for manufacturing a semiconductor device using the protective-film forming composition (the resist underlayer-film forming composition) according to the present invention will be described.

The protective film of the present invention is a baked product of a coating film formed of the protective-film forming composition of the present invention.

The resist underlayer film of the present invention is a baked product of a coating film formed of the resist underlayer-film forming composition of the present invention.

The method for manufacturing a substrate with a protective film of the present invention includes a step of applying the protective-film forming composition of the present invention to a semiconductor substrate and baking the protective-film forming composition to form a protective film. The method for manufacturing a substrate with a protective film is used for manufacturing a semiconductor.

A method for manufacturing a resist-patterned substrate of the present invention includes applying the protective-film forming composition of the present invention or the resist underlayer-film forming composition of the present invention onto a semiconductor substrate and baking the composition to form a protective film as a resist underlayer film, and forming a resist film on the protective film and then performing exposure and development to form a resist pattern. The method for manufacturing a resist-patterned substrate is used for manufacturing a semiconductor.

An embodiment of a method for manufacturing a semiconductor device of the present invention includes forming a protective film using the protective-film forming composition of the present invention on a semiconductor substrate having a surface on which an inorganic film is optionally formed, forming a resist pattern on the protective film, dry etching the protective film using the resist pattern as a mask to expose the inorganic film or the surface of the semiconductor substrate, and wet etching the inorganic film or the semiconductor substrate using the protective film after the dry etching as a mask by a semiconductor wet etching solution, followed by cleaning.

An embodiment of a method for manufacturing a semiconductor device of the present invention includes a step of forming a resist underlayer film using the resist underlayer-film forming composition of the present invention on a semiconductor substrate having a surface on which an inorganic film is optionally formed, forming a resist pattern on the resist underlayer film, dry etching the resist underlayer film using the resist pattern as a mask to expose the inorganic film or the surface of the semiconductor substrate, and etching the inorganic film or the semiconductor substrate using the resist underlayer film as a mask after the dry etching.

A resist-patterned substrate according to the present invention can be produced by applying the above-described protective-film forming composition (resist underlayer-film forming composition) onto a semiconductor substrate and baking the composition.

Examples of the semiconductor substrate onto which the protective-film forming composition (resist underlayer-film forming composition) of the present invention is applied include a silicon wafer, a germanium wafer, and a semiconductor wafer formed of a compound such as gallium arsenide, indium phosphide, gallium nitride, indium nitride, or aluminum nitride.

In the case of using the semiconductor substrate having a surface on which an inorganic film is formed, the inorganic film is formed by, for example, an atomic layer deposition (ALD) method, a chemical vapor deposition (CVD) method, a reactive sputtering method, an ion plating method, a vacuum deposition method, or a spin coating method (spin-on-glass, SOG). Examples of the inorganic film include a polysilicon film, a silicon oxide film, a silicon nitride film, a silicon oxynitride film, a boro-phospho silicate glass (BPSG) film, a titanium nitride film, a titanium oxynitride film, a tungsten nitride film, a gallium nitride film, and a gallium arsenide film. The semiconductor substrate may be a stepped substrate in which so-called vias (holes), trenches (grooves), and the like are formed. For example, the via has a substantially circular shape when viewed from an upper surface, a substantially circular diameter of the via is, for example, 2 nm to 20 nm, a depth of the via is 50 nm to 500 nm, a width of the groove (a recess of the substrate) of the trench is, for example, 2 nm to 20 nm, and a depth of the trench is 50 nm to 500 nm. Since the protective-film forming composition (resist underlayer-film forming composition) of the present invention has a small weight-average molecular weight and average particle size of the compound contained in the composition, the composition can be embedded even in the stepped substrate as described above without a defect such as a void. It is an important characteristic that there are no defects such as voids for the next step (wet etching and dry etching of semiconductor substrate, the formation of a resist pattern) of semiconductor manufacturing.

The protective-film forming composition (the resist underlayer-film forming composition) of the present invention is applied onto the semiconductor substrate by an appropriate coating method such as a spinner or a coater. Thereafter, baking is performed using heating means such as a hot plate to form a protective film (resist underlayer film). Conditions for baking are appropriately selected from a baking temperature of 100° C. to 400° C. and a baking time of 0.3 minutes to 60 minutes. The baking temperature is preferably 120° C. to 350° C. and the baking time is preferably 0.5 minutes to 30 minutes, and the baking temperature is more preferably 150° C. to 300° C., and the baking time is more preferably 0.8 minutes to 10 minutes. A thickness of the formed protective film is, for example, 0.001 μm to 10 μm, preferably 0.002 μm to 1 μm, and more preferably 0.005 μm to 0.5 μm. When the temperature during the baking is lower than the above range, the crosslinking may be insufficient, and the resistance of the formed protective film (resist underlayer film) to a resist solvent or a basic hydrogen peroxide aqueous solution may be hardly obtained. On the other hand, when the temperature during the baking is higher than the above range, the protective film (resist underlayer film) may be decomposed by heat.

A resist film is formed on the protective film formed as described above, and then exposed and developed to form a resist pattern.

The exposure is performed through a mask (reticle) for forming a predetermined pattern, and for example, an i-line, a KrF energy laser, an ArF energy laser, an extreme ultraviolet (EUV) ray, or an electron beam (EB) is used. An alkaline developer is used for development, and a development temperature is appropriately selected from 5° C. to 50° C., and a development time is appropriately selected from 10 seconds to 300 seconds. As the alkaline developer, for example, it is possible to use alkaline aqueous solutions such as aqueous solutions of inorganic alkalis such as sodium hydroxide, potassium hydroxide, sodium carbonate, sodium silicate, sodium metasilicate, and ammonia solutions, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, cyclic amines such as pyrrole and piperidine, and other alkaline aqueous solutions. Furthermore, it is also possible to add an appropriate amount of alcohols such as isopropyl alcohol or nonionic-based surfactants to the above alkaline aqueous solutions and use the resultant mixture. Among these, as the developers, it is preferable to use quaternary ammonium salts, and still more preferable to use tetramethylammonium hydroxide and choline. Furthermore, surfactants or other additives can be added to these developers. It is also possible to use a method in which development is performed with an organic solvent such as butyl acetate in place of the alkaline developer and a portion where the alkali dissolution rate of the photoresist is not improved is developed.

Next, the protective film (resist underlayer film) is dry-etched using the formed resist pattern as a mask. At that time, when the inorganic film is formed on the surface of the used semiconductor substrate, the surface of the inorganic film is exposed, and when the inorganic film is not formed on the surface of the used semiconductor substrate, the surface of the semiconductor substrate is exposed.

Furthermore, a desired pattern is formed by wet etching using a semiconductor wet etching solution using the protective film (resist underlayer film) (also the resist pattern in a case where the resist pattern remains on the protective film/resist underlayer film) after dry etching as a mask.

As the semiconductor wet etching solution, a general chemical for etching a semiconductor wafer can be used, and for example, both an acidic substance and a basic substance can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic hydrogen peroxide water obtained by mixing an organic amine such as ammonia, sodium hydroxide, potassium hydroxide, sodium cyanide, potassium cyanide, or triethanolamine with hydrogen peroxide water to make the pH basic. Specific examples thereof include SC-1 (ammonia-hydrogen peroxide solution). In addition, a substance capable of adjusting a pH to a basic pH, for example, a substance capable of finally adjusting a pH to a basic pH by mixing urea with aqueous hydrogen peroxide and causing thermal decomposition of urea by heating to generate ammonia, can be used as a chemical liquid for wet etching.

Among them, acidic hydrogen peroxide water or basic hydrogen peroxide water is preferable.

These chemicals may contain an additive such as a surfactant.

The temperature during use of the semiconductor wet etching solution is desirably 25° C. to 90° C., and more desirably 40° C. to 80° C. The wet etching time is desirably 0.5 minutes to 30 minutes, and more desirably 1 minute to 20 minutes.

### EXAMPLES

Hereinafter, the contents and effects of the present invention will be described in more detail by way of examples, but the present invention is not limited thereto.

The weight-average molecular weight of the compound synthesized in the following Examples of the present specification is a measurement result by gel permeation chromatography (hereinafter, abbreviated as GPC). In the measurement, a GPC apparatus manufactured by Tosoh Corporation was used, and measurement conditions and the like are as follows:
GPC column
Column temperature: 40° C.
Solvent: Tetrahydrofuran (THF)
Flow rate: 1.0 ml/min
Standard sample: Polystyrene (manufactured by Tosoh Corporation)

### Descriptions of Terms

PGME: Propylene glycol monomethyl ether
PGMEA: Propylene glycol monomethyl ether acetate

### Example 1

A solution with a solid content of 4.0 mass % was obtained by mixing 2.88 g (a weight-average molecular weight of 3100) of an epoxy novolac resin EOCN-104S (manufactured by Nippon Kayaku Co., Ltd.; corresponding to the following Formula (α-1)), 0.72 g of VP-2500 (manufactured by Nippon Soda Co., Ltd.; corresponding to the following Formula (e-1), a weight average molecular weight of 3687), 0.043 g of 1B2PZ (manufactured by SHIKOKU CHEMICALS CORPORATION; corresponding to the following Formula (d-1)), 0.29 g of 1,2-hexanediol (manufactured by Tokyo Chemical Industry Co., Ltd.; corresponding to the following Formula (f-1)), 0.58 g of TMMP (manufactured by SC Organic Chemical Co., Ltd.; corresponding to the following Formula (b-1)), 28.65 g of PGMEA, and 66.85 g of PGME. The solution was filtered using a polytetrafluoroethylene microfilter having a pore size of 0.2 μm to prepare a protective-film forming composition.

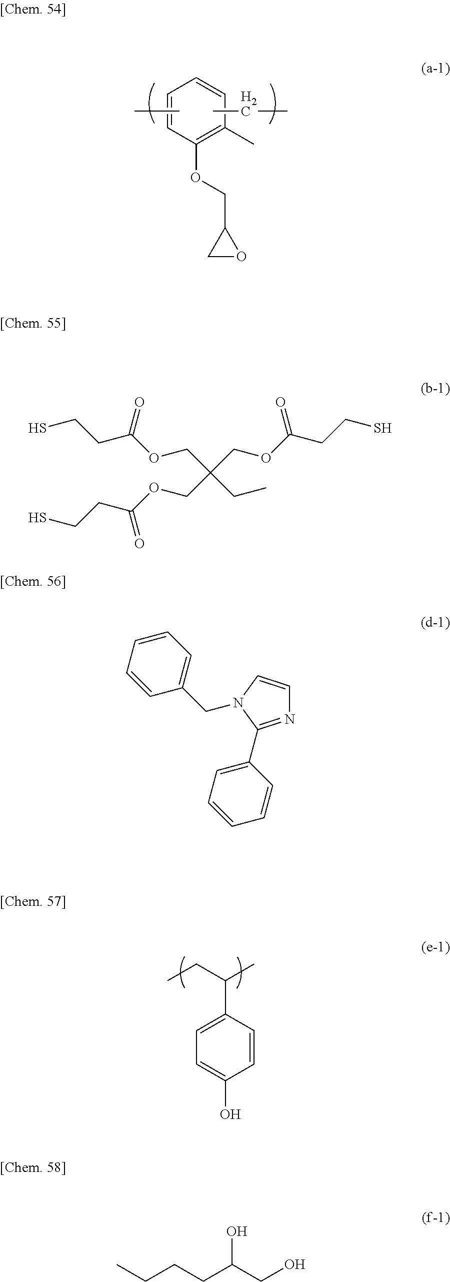

### Example 2

A solution with a solid content of 4.0 mass % was obtained by mixing 2.88 g (a weight-average molecular weight of 3100) of an epoxy novolac resin EOCN-104S (manufactured by Nippon Kayaku Co., Ltd.), 0.72 g of VP-2500 (manufactured by Nippon Soda Co., Ltd., a weight average molecular weight of 3687), 0.043 g of 1B2PZ (manufactured by SHIKOKU CHEMICALS CORPORATION), 0.29 g of 1,2-hexanediol (manufactured by Tokyo Chemical Industry Co., Ltd.), 0.58 g of TEMPIC (manufactured by SC Organic Chemical Co., Ltd.; corresponding to the following Formula (b-2)), 28.65 g of PGMEA, and 66.85 g of PGME. The solution was filtered using a polytetrafluoroethylene microfilter having a pore size of 0.2 μm to prepare a protective-film forming composition.

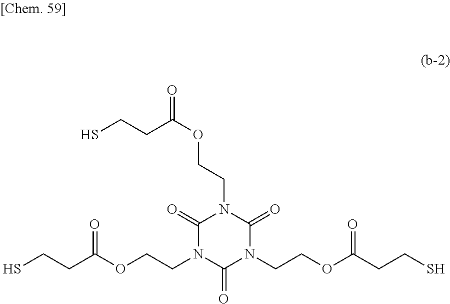 [SMILES: O=C(CCS)OCCn1c(=O)n(CCOC(=O)CCS)c(=O)n(CCOC(=O)CCS)c1=O]

### Example 3

A solution with a solid content of 4.0 mass % was obtained by mixing 2.88 g (a weight-average molecular weight of 3100) of an epoxy novolac resin EOCN-104S (manufactured by Nippon Kayaku Co., Ltd.), 0.72 g of VP-2500 (manufactured by Nippon Soda Co., Ltd., a weight average molecular weight of 3687), 0.043 g of 1B2PZ (manufactured by SHIKOKU CHEMICALS CORPORATION), 0.29 g of 1,2-hexanediol (manufactured by Tokyo Chemical Industry Co., Ltd.), 0.58 g of KarenzMT (registered trademark) TPMB (manufactured by Resonac Holdings Corporation; corresponding to the following Formula (b-3)), 28.65 g of PGMEA, and 66.85 g of PGME. The solution was filtered using a polytetrafluoroethylene microfilter having a pore size of 0.2 μm to prepare a protective-film forming composition.

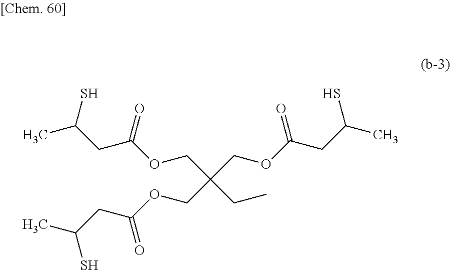 [SMILES: CCC(COC(=O)CC(C)S)(COC(=O)CC(C)S)COC(=O)CC(C)S]

### Example 4

A solution with a solid content of 4.0 mass % was obtained by mixing 2.88 g (a weight-average molecular weight of 3100) of an epoxy novolac resin EOCN-104S (manufactured by Nippon Kayaku Co., Ltd.), 0.72 g of VP-2500 (manufactured by Nippon Soda Co., Ltd., a weight average molecular weight of 3687), 0.043 g of 1B2PZ (manufactured by SHIKOKU CHEMICALS CORPORATION), 0.29 g of 1,2-hexanediol (manufactured by Tokyo Chemical Industry Co., Ltd.), 0.58 g of KarenzMT (registered trademark) NR1 (manufactured by Resonac Holdings Corporation; corresponding to the following Formula (b-4)), 28.65 g of PGMEA, and 66.85 g of PGME. The solution was filtered using a polytetrafluoroethylene microfilter having a pore size of 0.2 μm to prepare a protective-film forming composition.

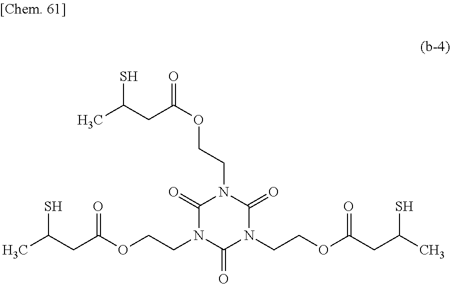 [SMILES: CC(S)CC(=O)OCCn1c(=O)n(CCOC(=O)CC(C)S)c(=O)n(CCOC(=O)CC(C)S)c1=O]

### Comparative Example 1

A solution with a solid content of 4.0 mass % was obtained by mixing 3.30 g (a weight-average molecular weight of 3100) of an epoxy novolac resin EOCN-104S (manufactured by Nippon Kayaku Co., Ltd.), 0.82 g of VP-2500 (manufactured by Nippon Soda Co., Ltd., a weight average molecular weight of 3687), 0.049 g of 1B2PZ (manufactured by SHIKOKU CHEMICALS CORPORATION), 0.33 g of 1,2-hexanediol (manufactured by Tokyo Chemical Industry Co., Ltd.), 28.65 g of PGMEA, and 66.85 g of PGME. The solution was filtered using a polytetrafluoroethylene microfilter having a pore size of 0.2 μm to prepare a protective-film forming composition.

### Comparative Example 2

A solution with a solid content of 4.0 mass % was obtained by mixing 2.88 g (a weight-average molecular weight of 3100) of an epoxy novolac resin EOCN-104S (manufactured by Nippon Kayaku Co., Ltd.), 0.72 g of VP-2500 (manufactured by Nippon Soda Co., Ltd., a weight average molecular weight of 3687), 0.043 g of 1B2PZ (manufactured by SHIKOKU CHEMICALS CORPORATION), 0.29 g of 1,2-hexanediol (manufactured by Tokyo Chemical Industry Co., Ltd.), 0.58 g of NIKALAC Mw-390 (manufactured by SANWA CHEMICAL CO., LTD.; corresponding to the following Formula (b2-1)), 28.65 g of PGMEA, and 66.85 g of PGME. The solution was filtered using a polytetrafluoroethylene microfilter having a pore size of 0.2 μm to prepare a protective-film forming composition.

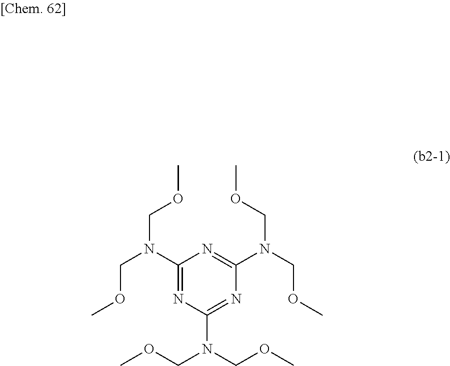

### Comparative Example 3

A solution with a solid content of 4.0 mass % was obtained by mixing 2.55 g (a weight-average molecular weight of 3100) of an epoxy novolac resin EOCN-104S (manufactured by Nippon Kayaku Co., Ltd.), 0.64 g of VP-2500 (manufactured by Nippon Soda Co., Ltd., a weight average molecular weight of 3687), 0.038 g of 1B2PZ (manufactured by SHIKOKU CHEMICALS CORPORATION), 0.25 g of 1,2-hexanediol (manufactured by Tokyo Chemical Industry Co., Ltd.), 1.02 g of NIKALAC Mw-390 (manufactured by SANWA CHEMICAL CO., LTD.), 28.65 g of PGMEA, and 66.85 g of PGME. The solution was filtered using a polytetrafluoroethylene microfilter having a pore size of 0.2 μm to prepare a protective-film forming composition.

### (Test of Resistance to Basic Hydrogen Peroxide Aqueous Solution)

Each of the protective-film forming compositions prepared in Examples 1 to 4 and the protective-film forming composition prepared in Comparative Examples 1 to 3 was applied to the silicon substrate having the surface on which the titanium nitride film was formed, and baked at 250° C. to produce a coating film, and the coating film was immersed in a basic hydrogen peroxide aqueous solution having the composition as shown in Table 1 at the temperature shown in the same table for 3 minutes, washed with water, and dried, and the state of the coating film was then visually observed. The results are shown in Table 2 below. “x” indicates a state in which the film is peeled off, and “∘” indicates a state in which the film is not peeled off.

TABLE 1

| | 33 mass % | | |
|---|---|---|---|
| 28 mass % | hydrogen | | |
| ammonia | peroxide aqueous | Ultrapure | |
| solution | solution | water | Temperature |
| 40 mL | 40 mL | 80 mL | 50° C. |

### (Measurement Test of Dry Etching Rate)

In the measurement of a dry etching rate, the following etcher and etching gas were used.
Lam2300 (manufactured by LAM RESEARCH CORPORATION): H₂/N₂

Using a coating film produced by applying each of the protective-film forming compositions prepared in Examples 1 to 4 and the protective-film forming compositions prepared in Comparative Examples 1 to 3 to a silicon substrate, and baking the composition at 250° C., the rate was measured by comparing the reduction amount of the film thickness before and after dry etching. The results are shown in Table 2. In Table 2, the reduction amount of the film thickness of Comparative Example 1 is set as 1, and each of film thickness reduction ratios of Examples 1 to 4 and Comparative Examples 2 and 3 is indicated.

### (Resistance Test to Organic Solvent)

A coating film produced by applying each of the protective-film forming compositions prepared in Examples 1 to 4 and the protective-film forming compositions prepared in Comparative Examples 1 to 3 to a silicon substrate, and baking the composition at 250° C. was immersed in a mixture of PGME and PGMEA, serving as a solvent used for a photoresist solution, at a ratio of 7:3, and the film thicknesses before and after the immersion were compared to confirm that the coating film was insoluble in the solvent. As a result of the measurement, the case where the film thickness decreased by only 1% or less and was insoluble was evaluated as “∘”, and the case where the film thickness decreased by 1% or more and was soluble was evaluated as “x”. The results are shown in Table 2.

TABLE 2

| | | | Resistance | |
|---|---|---|---|---|
| | | | test to | |
| | | | basic | |
| | Carbon | Measurement | hydrogen | Resistance |
| | content of | test of dry | peroxide | test to |
| | the entire | etching | aqueous | organic |
| | composition | rate | solution | solvent |
| Example 1 | 71 mass % | 1.07 | ∘ | ∘ |
| Example 2 | 71 mass % | 1.05 | ∘ | ∘ |
| Example 3 | 72 mass % | 1.06 | ∘ | ∘ |
| Example 4 | 71 mass % | 1.04 | ∘ | ∘ |
| Comparative | 75 mass % | 1.00 | ∘ | ∘ |
| Example 1 | | (reference) | | |
| Comparative | 71 mass % | 0.99 | ∘ | ∘ |
| Example 2 | | | | |
| Comparative | 68 mass % | 0.98 | ∘ | ∘ |
| Example 3 | | | | |

In general, a higher etch rate (ER) can be expected as the carbon content is lower, but in Comparative Examples 2 and 3, the ER is substantially unchanged. This is considered to be because NIKALAC Mw390 barely reacted with EOCN-104S or VP-2500 and did not remain in the cured film.

On the other hand, in Examples 1 to 4 containing the compound having a thiol structure, the etch rate (ER) is increased by 4% to 7% by adding 20 mass % with respect to the addition amount of EOCN-104S. This is considered to be because the compound having a thiol structure reacted with epoxy groups in the compound or polymer (A) and remained in the film.

As described above, Examples 1 to 4 containing the compound having a thiol structure have a higher etch rate (ER) than Comparative Examples 1 to 3.

From the results in Table 2, it was found that the coating film prepared using each of the protective-film forming compositions prepared in Examples 1 to 4 had a high resistance to a basic hydrogen peroxide aqueous solution, while being able to improve the etch rate (ER) as compared to Comparative Examples 1 to 3.

### INDUSTRIAL APPLICABILITY

Since the protective-film forming composition according to the present invention has excellent resistance when a wet etching solution is applied in substrate processing, the protective-film forming composition is one for providing a protective film which is less damaged during substrate processing. Furthermore, the protective-film forming composition according to the present invention can provide a protective film enabling dry etching at a high etching speed to achieve a high etch rate (ER). In addition, the resist underlayer-film forming composition according to the present invention has excellent resistance when a wet etching solution is applied in substrate processing, and is also excellent in achieving a high etch rate (ER).

1. A protective-film forming composition against a semiconductor wet etching solution, the protective-film forming composition comprising:
(A) a compound or polymer having an epoxy structure represented by the following Formula (I);
(B) a compound having a thiol structure; and
(C) a solvent, 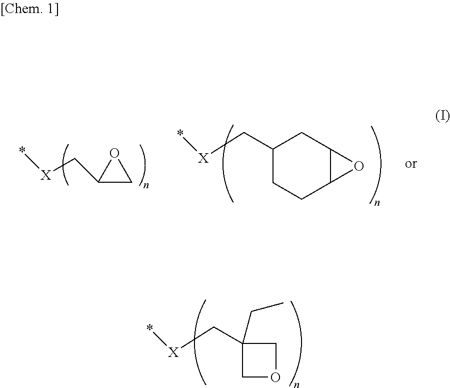
in formula (I), * represents a binding site; n represents 1 or 2; and when n=1, X represents an ether bond, an ester bond, or an amide bond, and when n=2, X represents a nitrogen atom or an amide bond.

2. The protective-film forming composition according to claim 1, further comprising (D) a curing agent.

3. The protective-film forming composition according to claim 1, further comprising (E) a compound or polymer having a phenolic hydroxy group.

4. The protective-film forming composition according to claim 1, wherein the compound (A) is a compound having a partial structure represented by the following Formula (III), 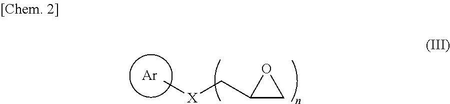
in Formula (III), Ar represents a benzene ring, a naphthalene ring, or an anthracene ring; n is 1 or 2; and when n=1, X represents an ether bond, an ester bond, or an amide bond, and when n=2, X represents a nitrogen atom or an amide bond.

5. The protective-film forming composition according to claim 1, wherein the polymer (A) is a polymer having a novolac structure having a unit structure represented by the following Formula (1-1), 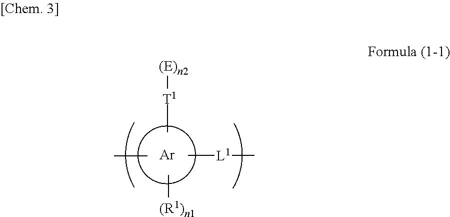
in Formula (1-1), Ar represents a benzene ring, a naphthalene ring, or an anthracene ring, R¹ represents a hydroxy group, a mercapto group which may be protected by a methyl group, an amino group which may be protected by a methyl group, a halogeno group, or an alkyl group having 1 to 10 carbon atoms, which may be substituted with or interrupted by a heteroatom and may be substituted with a hydroxy group, n1 represents an integer of 0 to 3, L¹ represents a single bond or an alkylene group having 1 to 10 carbon atoms, n2 represents 1 or 2, E represents a group having an epoxy group or a group having an oxetanyl group, T¹ represents an alkylene group having 1 to 10 carbon atoms, which may be interrupted by an ether bond, an ester bond, or an amide bond when n2=1, and T¹ represents a trivalent hydrocarbon group having 1 to 10 carbon atoms, which may be interrupted by a nitrogen atom or an amide bond when n2=2.

6. The protective-film forming composition according to claim 1, wherein the compound (B) having a thiol structure is a polyfunctional thiol compound represented by the following Formula (10-1), 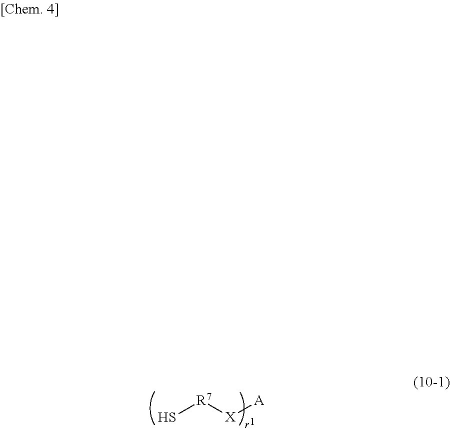
in Formula (10-1) R⁷ represents a single bond or a linear or branched alkylene group having 1 to 6 carbon atoms, X represents a single bond or an ester bond, A represents an organic group having 2 to 12 carbon atoms or a heteroatom, and r¹ represents an integer of 2 to 6.

7. The protective-film forming composition according to claim 2, wherein the curing agent (D) is a base.

8. The protective-film forming composition according to claim 7, wherein the base is an imidazole-based compound.

9. The protective-film forming composition according to claim 8, wherein the base is represented by the following Formula (B1), 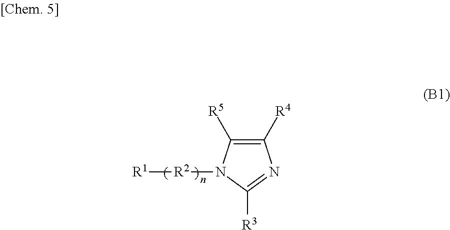
in Formula (B1), R¹ represents a hydrogen atom, an alkyl group having 1 to 4 carbon atoms, an aryl group which may be substituted, a monovalent group obtained by removing, from a triazine ring which may be substituted, a hydrogen atom bonded to a carbon atom of the triazine ring, a cyano group, a hydroxy group, an amino group, a vinyl group, an acryloyloxy group, or a methacryloyloxy group, R² represents an alkylene group having 1 to 4 carbon atoms, R³ represents a hydrogen atom, an alkyl group having 1 to 17 carbon atoms, or an aryl group which may be substituted, R⁴ represents a hydrogen atom, a formyl group, an alkyl group having 1 to 4 carbon atoms, which may be substituted, or an alkoxyalkyl group having 4 or less carbon atoms, which may be substituted, R⁵ represents a hydrogen atom, a formyl group, an alkyl group having 1 to 4 carbon atoms, which may be substituted, or an alkoxyalkyl group having 4 or less carbon atoms, which may be substituted, and n represents 0 or 1.

10. The protective-film forming composition according to claim 3, wherein the compound or polymer having a phenolic hydroxy group (E) has two or more phenolic hydroxy groups.

11. The protective-film forming composition according to claim 3, wherein the compound or polymer having a phenolic hydroxy group (E) is a polymer having a unit structure represented by the following Formula (3-1), 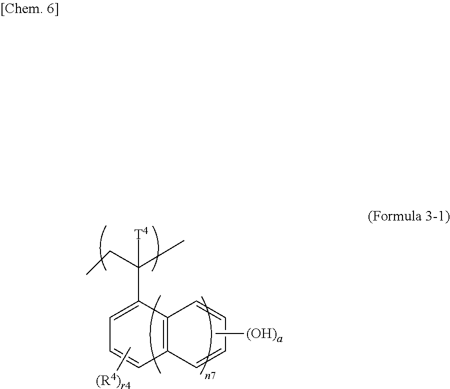
wherein, T⁴ represents a hydrogen atom or an alkyl group having 1 to 10 carbon atoms, which may be substituted with a halogeno group; R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, or an alkyl group having 1 to 10 carbon atoms, which may be substituted with a hydroxy group or a halogeno group; r4 represents an integer of 0 to 3; n7 represents an integer of 0 to 2; and a represents an integer of 1 to 6.

12. A protective film against a semiconductor wet etching solution, wherein the protective film is a baked product of a coating film containing the protective-film forming composition according to claim 1.

13. A resist underlayer-film forming composition comprising:
(A) a compound or polymer having an epoxy structure represented by the following Formula (I);
(B) a compound having a thiol structure; and
(C) a solvent, 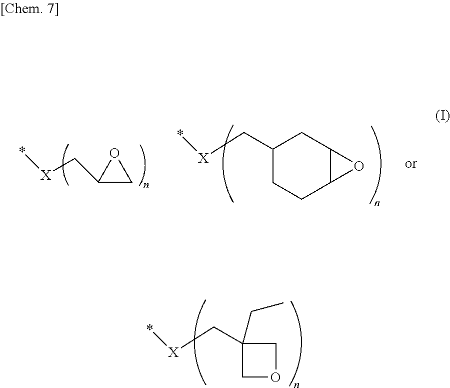
in Formula (I), * represents a binding site; n represents 1 or 2; and when n=1, X represents an ether bond, an ester bond, or an amide bond, and when n=2, X represents a nitrogen atom or an amide bond.

14. A method for manufacturing a substrate with a protective film, the method comprising: a step of applying the protective-film forming composition according to claim 1 to a semiconductor substrate, and baking the composition to form a protective film, wherein the method is used for manufacturing a semiconductor.

15. A method for manufacturing a resist-patterned substrate, the method comprising: a step of applying the protective-film forming composition according to claim 1 or the resist underlayer-film forming composition comprising:
(A) the compound or polymer having the epoxy structure represented by the following Formula (I);
(B) the compound having the thiol structure; and
(C) the solvent, 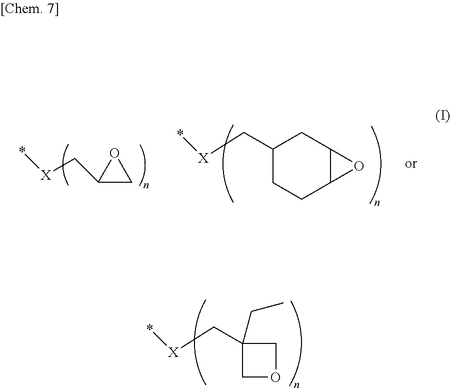
in Formula (I), * represents the binding site; n represents 1 or 2; and when n=1, X represents the ether bond, the ester bond, or the amide bond, and when n=2, X represents the nitrogen atom or the amide bond to a semiconductor substrate and baking the composition to form a protective film as a resist underlayer film; and a step of forming a resist film on the protective film and then exposing and developing the composition to form a resist pattern, wherein the method is used for manufacturing a semiconductor.

16. A method for manufacturing a semiconductor device, the method comprising a step of: forming a protective film using the protective-film forming composition according to claim 1 on a semiconductor substrate having a surface on which an inorganic film is optionally formed; forming a resist pattern on the protective film; dry etching the protective film using the resist pattern as a mask to expose the inorganic film or the surface of the semiconductor substrate; and wet etching the inorganic film or the semiconductor substrate using the protective film after the dry etching as a mask by a semiconductor wet etching solution, followed by cleaning.

17. A method for manufacturing a semiconductor device, the method comprising a step of: forming a resist underlayer film using the resist underlayer-film forming composition according to claim 13 on a semiconductor substrate having a surface on which an inorganic film is optionally formed; forming a resist pattern on the resist underlayer film; dry etching the resist underlayer film using the resist pattern as a mask to expose the inorganic film or the surface of the semiconductor substrate; and etching the inorganic film or the semiconductor substrate using the resist underlayer film as a mask after the dry etching.
